(19) United States
(12) Patent Application Publication
(10) Pub. No.: US 2023/0329117 A1
(43) Pub. Date: Oct. 12, 2023

(54) DEEP SMOOTH ETCHING TO REALIZE SCALABLE DEVICES HAVING PIEZOELECTRIC CRYSTALS

(71) Applicants: Tito Busani, Albuquerque, NM (US); Arjun Aryal, Albuquerque, NM (US); Aleem Mohammad Siddiqui, Albuquerque, NM (US); Mahmoud Behzadirad, Albuquerque, NM (US); Ravi Kiran Chityala, Albuquerque, NM (US); Abu Shami MD Zadis Shifat, Albuquerque, NM (US); Isaac Edward Stricklin, Albuquerque, NM (US)

(72) Inventors: Tito Busani, Albuquerque, NM (US); Arjun Aryal, Albuquerque, NM (US); Aleem Mohammad Siddiqui, Albuquerque, NM (US); Mahmoud Behzadirad, Albuquerque, NM (US); Ravi Kiran Chityala, Albuquerque, NM (US); Abu Shami MD Zadis Shifat, Albuquerque, NM (US); Isaac Edward Stricklin, Albuquerque, NM (US)

(21) Appl. No.: 18/298,790

(22) Filed: Apr. 11, 2023

Related U.S. Application Data
(60) Provisional application No. 63/330,103, filed on Apr. 12, 2022.

(51) Int. Cl. H10N 30/082; H01J 37/32; H10N 30/853

(52) U.S. Cl. CPC H10N 30/082; H01J 37/321; H01J 2237/336; H01J 2237/334; H10N 30/8542

(57) ABSTRACT

An inductively coupled plasma dry etch process can obtain a deep etching profile in a piezoelectric material, such as lithium niobate, with minimum roughness and substantially vertical sidewalls. In addition, quality metal masks can be achieved by employing a hydrogen-plasma treatment prior to the processing steps. Periodic interruption steps can be included in the plasma dry etch procedure followed by a chemical cleaning between each cycle to avoid thermal effect and minimize byproduct redeposition during the long etching process. A deep etching profile in a piezoelectric material, such as a ScₓAl₁₋ₓN film, can be attained with minimum roughness and substantially vertical sidewalls using wet etching and a patterned mask, where the patterned mask is formed using another mask.

### RELATED APPLICATION

This application claims priority under 35 U.S.C. 119(e) from U.S. Provisional Application Ser. No. 63/330,103, filed 12 Apr. 2022, which application is incorporated herein by reference in its entirety.

### GOVERNMENT FUNDING

This invention was made with government support under DE-NA0003525 awarded by Department of Energy-Sandia National Labs. The government has certain rights in the invention.

### FIELD OF THE INVENTION

The invention relates generally to piezoelectric materials along with fabrication and use of the same.

### BACKGROUND

The exceptional material properties of lithium niobate (LiNbO₃) make lithium niobate an excellent material for a wide range of RF, micro-electromechanical systems (MEMS), phononic applications, and photonic applications. However, nano-scale and micro-scale devices using lithium niobate typically depend on high fidelity processing of lithium niobate films. Enhancements to the design and fabrication of lithium niobate-based devices can provide for further advancement of related technologies.

### BRIEF DESCRIPTION OF THE DRAWINGS

Embodiments of the invention are illustrated by way of example and not limitation in the figures of the accompanying drawings in which:

FIGS. 1A-1C represent two-dimensional and three-dimensional piezoelectric phononic crystals, in accordance with various embodiments.

FIGS. 2A-2F show a schematic of a fabrication process to form patterns on samples having piezoelectric material, in accordance with various embodiments.

FIG. 3 shows a scanning electron microscope image of a top view of a sample after lithography, in accordance with various embodiments.

FIG. 4 shows a scanning electron microscope image of a side view of a patterned photoresist after lithography, in accordance with various embodiments.

FIGS. 5A-5E show a comparison of titanium/aluminum mask quality on different lithium niobate cuts, in accordance with various embodiments.

FIGS. 6A-6E show a comparison of titanium/aluminum/chromium mask quality on different lithium niobate cuts, in accordance with various embodiments.

FIGS. 7A-7B show metal mask quality on X-cut lithium niobate and Y-cut lithium niobate after employing hydrogen-plasma treatment, in accordance with various embodiments.

FIGS. 8A-8B show etching 128YX lithium niobate using trifluoromethane/argon gas with combinations of metal masks, in accordance with various embodiments.

FIGS. 9A-9B show verticality measurements for the features with metal masks and etched 128Y oriented lithium niobate with metal masks using trifluoromethane/argon gases, in accordance with various embodiments.

FIGS. 10A-10E show inductively coupled plasma etching of a micro-structure using trifluoromethane/argon gases with titanium/aluminum/chromium metal masks, in accordance with various embodiments.

FIGS. 11A-11C show 128YX lithium niobate dry etched with an aluminum mask using a sulfur hexafluoride plasma, in accordance with various embodiments.

FIGS. 12A-12B show 128YX lithium niobate dry etched with an aluminum mask using a trifluoromethane/argon plasma, in accordance with various embodiments.

FIGS. 13A-13B show 128YX lithium niobate dry etched with a chromium mask using a trifluoromethane/argon plasma, in accordance with various embodiments.

FIGS. 14A-14B show 128YX lithium niobate dry etched with a chromium mask using a trifluoromethane/argon plasma, in accordance with various embodiments.

FIG. 15 shows re-deposition of lithium niobate by-products with an aluminum mask, in accordance with various embodiments.

FIGS. 16A-16B show peeling off metal films X cut only lithium niobate/silicon, in accordance with various embodiments.

FIGS. 17A-17B show peeling off metal films Y cut only lithium niobate/silicon, in accordance with various embodiments.

FIGS. 18A-18B show results with respect to plasma treatment and etching, in accordance with various embodiments.

FIGS. 19A-19B show results with respect to plasma treatment and etching, in accordance with various embodiments.

FIG. 20 shows etched lithium niobate, in accordance with various embodiments.

FIG. 21 represents images of a device having etched lithium niobate, in accordance with various embodiments.

FIG. 22 shows radio frequency testing for a one micron etched lithium niobate, in accordance with various embodiments.

FIG. 23 shows a partial release structure, in accordance with various embodiments.

FIG. 24 is a flow diagram of features of an example method of processing a piezoelectric material, in accordance with various embodiments.

FIG. 25 is a flow diagram of features of an example method of processing lithium niobate, in accordance with various embodiments.

FIG. 26 is a table providing a summary of promising dry etching process results for scandium-aluminum-nitrogen compositions, in accordance with various embodiments.

FIG. 27 is a table providing a summary of promising wet etching process results for scandium-aluminum-nitrogen compositions, in accordance with various embodiments.

FIGS. 28A-28I illustrates features of etch processing for thin films having a piezoelectric material, in accordance with various embodiments.

FIGS. 29A-29B are scanning electron microscopy images of a scandium-aluminum-nitrogen composition having a rough surface with abnormally oriented grains, in accordance with various embodiments.

FIGS. 30A-30D are scanning electron microscopy images of scandium-aluminum-nitrogen compositions after different etching, in accordance with various embodiments.

FIGS. 31A-31D show results of using the same tetramethyl ammonium hydroxide concentration and temperature during the etching process of scandium-aluminum-nitrogen compositions, accordance with various embodiments.

FIG. 32 is a flow diagram of features of an example method of processing piezoelectric material, in accordance with various embodiments.

### DETAILED DESCRIPTION

The following detailed description refers to the accompanying drawings that show, by way of illustration and not limitation, various example embodiments of the invention. These embodiments are described in sufficient detail to enable those skilled in the art to practice these and other embodiments. In order to avoid obscuring embodiments of the invention, some well-known system configurations and process steps are not disclosed in detail. Other embodiments may be utilized, and structural, logical, and electrical changes may be made to these embodiments. The various embodiments are not necessarily mutually exclusive, as some embodiments can be combined with one or more other embodiments to form new embodiments. The following detailed description is, therefore, not to be taken in a limiting sense.

In various embodiments, procedures can be used to fabricate and measure three-dimensional (3D) piezoelectric phononic crystals. Such procedures, for example, can employ epitaxial transfer and lift off and deposition techniques to build up laminated thin film piezoelectric lithium niobate alternated with amorphous silicon. Lithium niobate, including varying stoichiometries, is herein referred to as LN. Interferometric lithograph, wet and dry fluorine electron cyclotron resonance (ECR), wet and dry chlorine electron cyclotron resonance (ECR) etching, and contact lithography, can be used to etch layer-by-layer as a structure is stacked up. Such a process can realize, but is not limited to, a pristine 3D phononic crystal at XBAND frequencies. ECR etching can include wet or dry fluorine ECR etching, wet or dry chlorine ECR etching, or combinations thereof. This structure represents the maturation of processing technology and can be the bases to impact addressing high density radio frequency (RF) systems, topological acoustics, and exotic nonlinear phononics.

Beyond disclosing a robust etching method to realize a 3D piezoelectric phononic crystal and high-quality stacked lithium niobate resonators, the present disclosure includes details regarding how to fabricate such device. Such disclosures can include, but are not limited to, the following processes: (1) near perfect etching realized by dry etching, combination chromium/aluminum (Cr/Al) hard mask, and hydrogen plasma surface treatment, and (2) epitaxial transfer and bonding. Key technical accomplishments can include optimized LN etch for vertical side walls, re-disposition, and improvement in smoothness, first pass interferometric lithography on gallium nitride (GaN), and fabricated and tested initial RF devices for filters, anisotropic focusing, and traveling wave acoustics.

LN's exceptional material properties make it an excellent material platform for a wide range of RF, micro-electromechanical systems (MEMS), phononic applications, and photonic applications. However, nanomicro scale device concepts typically depend on high fidelity processing of LN films. Herein, a highly optimized processing methodology is disclosed that can achieve a deep etch with nearly vertical and smooth sidewalls. It is demonstrated that titanium/aluminum/chromium (Ti/Al/Cr) stack works exceptionally well as a hard mask material during long plasma dry-etching. Periodically pausing the etching and chemical cleaning between cycles can be leveraged to avoid thermal effects and byproduct redeposition. To improve mask quality on X-cut and Y-cut substrates, a hydrogen (H₂)-plasma treatment can be implemented to relieve surface tension by modifying the top surface atoms. Structures with etch depths as deep as 3.4 μm can be obtained in the processing, as taught herein, across a range of crystallographic orientations with a smooth sidewall and perfect or near-perfect verticality on all crystallographic facets.

LN has proven to be the material of choice for a wide range of applications due to its exceptional piezoelectric, electro-acoustical, electro-optical, and non-linear optical properties. Different crystalline orientations of LN are heavily utilized for applications in surface-acoustic-wave (SAW) resonators, optical filters, optical sensors, modulators, transducers, optical waveguides, Q-switch lasers, oscillators, and other applications.

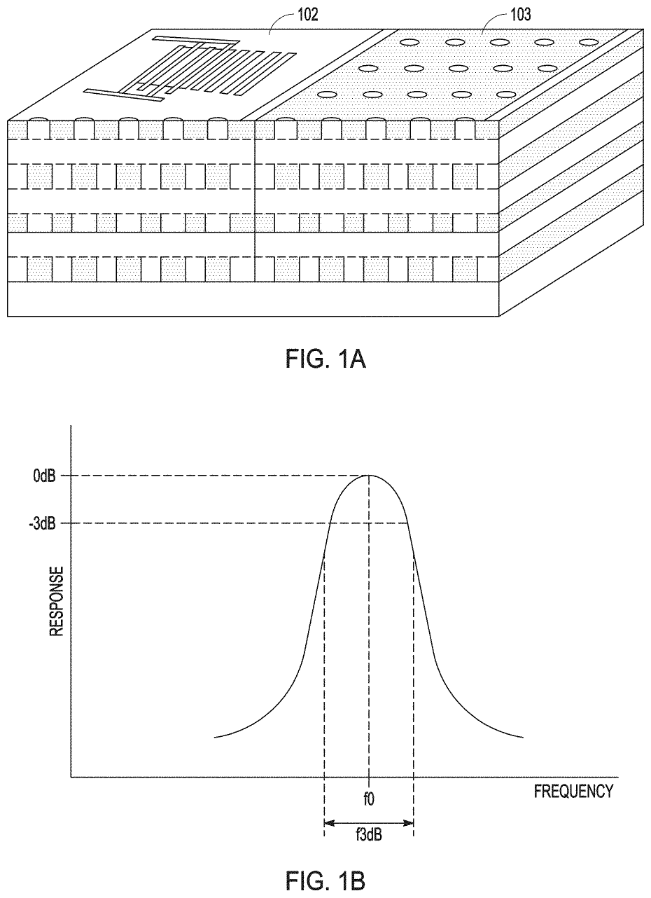

FIGS. 1A-1C represent two-dimensional (2D) and 3D piezoelectric phononic crystals. FIG. 1A shows an embodiment of an example 2D piezoelectric phononic crystal 102 and an example 3D piezoelectric phononic crystal 103 in stacked LN thin films. Such structures can provide spatial confinement and periodic nanostructuring. FIG. 1B shows a frequency response from a quality factor (Q=f₀/f_{3dB}) measurement showing the center frequency f₀ and −3 dB points. FIG. 1C shows applications of such phononic crystals.

At the nano-scale and micro-scale, device performance is often constrained by the fabrication quality of processed LN films. Unlike many semiconductors and dielectric materials, LN substrates are complex for processing and have been notoriously difficult to etch. Typically, in conventional processing, a long plasma dry-etch is required to obtain high-aspect ratio or deep etching profiles in LN substrates. To address such issues, a successful LN etching process is disclosed herein to manage one or more factors including substrate heating, redeposition of the etching products and mask materials, and durability of the mask materials over the etching process.

Dry etching of LN substrates has been studied by different research groups and different plasma etch conditions have been investigated to optimize the quality of the resulting structures. Fluorine (F₂) based plasma sources have most commonly been used to etch LN. However, use of a fluorine-based plasma source is accompanied by the redeposition of LiF and its byproducts, which reduces the etching rate and creates unfavorable features due to local micro-masking effects. The byproducts from fluorine-based dry-etch evaporate at only at 800° C., thus remaining on the surfaces and the sidewalls of the structure. This has been reported to not only reduce the etch rate of the target material, but to also prevent obtaining vertical etching profiles. Additionally, typical mask material delaminates or are otherwise consumed during the etching process resulting in roughness on the etched structure, which can degrade performance. Degraded performance can include, for example, increased optical losses due to surface roughness. Adding argon (Ar) gas to the chemistry of the plasma etching has been reported to enhance the physical sputtering (etching) process and obtain more uniform etching profile, thus mitigating portion of these challenges during the dry etch.

To overcome the problem of redeposition of product compounds, LN concentration on the top surface should be minimized. This can be achievable, as reported in the literature, by employing a proton exchange (PE) process where some of the lithium ions are replaced by protons in the LN crystal structure. It has been shown that the PE process will significantly reduce the amount of LiF redeposition, and therefore it increases the etching rate and improves the etching profiles as well. However, the PE process is expensive, not available for all process, and time consuming, therefore, process enhancements, as taught herein, can be achieved with an alternative to replace the PE process with a cost-effective and a more available method.

In various embodiments, progress in etching different crystalline LN substrates can be provided using inductively coupled plasma (ICP). By comparing different combination of the mask materials on different LN orientations (cuts), optimum dry etch condition to obtain deep etching profiles on all orientations with smooth and vertical sidewalls is presented herein. Also demonstrated is that employing a H₂-plasma treatment prior to the processing, as an alternative for PE process, overcomes delamination of the metal mask on X-cut and Y-cut LN samples and improves the quality of the etching profile.

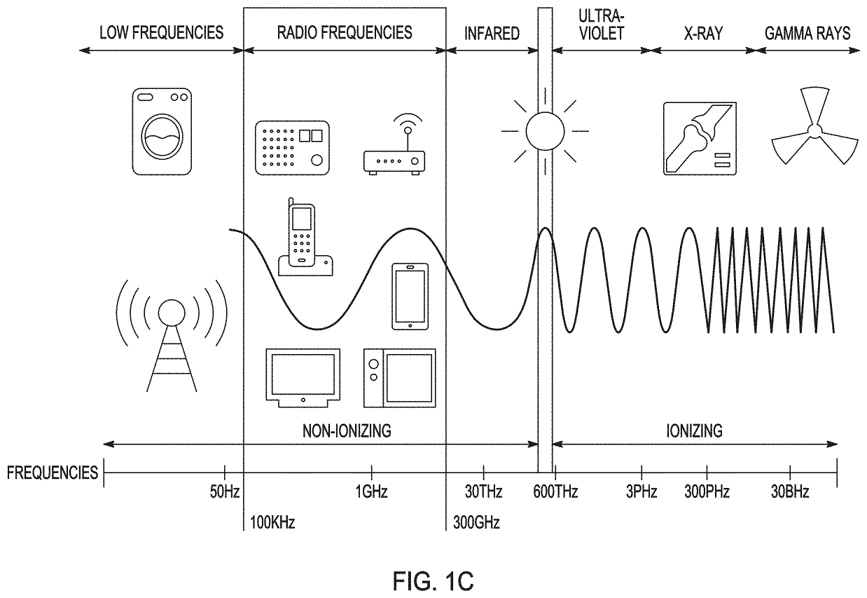

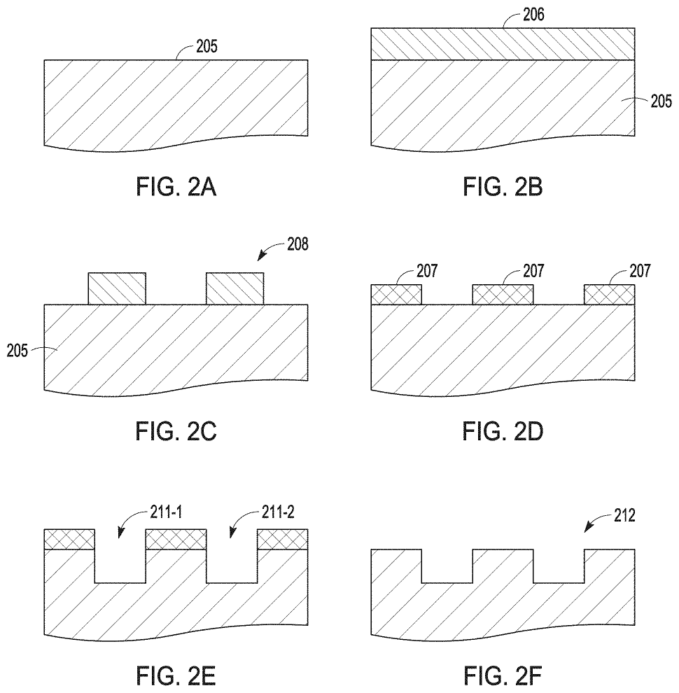

FIGS. 2A-2F illustrate a fabrication procedure that can be applied to preparing piezoelectric material, such as but not limited to piezoelectric phononic crystals of LN, for various applications. FIG. 2A illustrates provision of a substrate 205 having the appropriate piezoelectric material. Substrate 205 can be, for example, a LN-based substrate. FIG. 2B illustrates a photoresist 206 applied to substrate 205. Photoresist 206 can be applied by spin coating. Other appropriate techniques can be used to apply photoresist 206. FIG. 3C illustrates forming a pattern 208 to the photoresist 206. Pattern 208 can be formed by photolithography. FIG. 2D illustrates results of metallization 207 and lift-off using the pattern of FIG. 3C. FIG. 2E illustrates results of applying an ICP dry etch to the substrate of FIG. 2D, forming openings 211-1 and 211-2, which can have vertical sidewalls. FIG. 2F illustrates results of removal of metal mask, formed of metallization 207, forming a pattern 212 in substrate 205. This process can be applied to a more complex design.

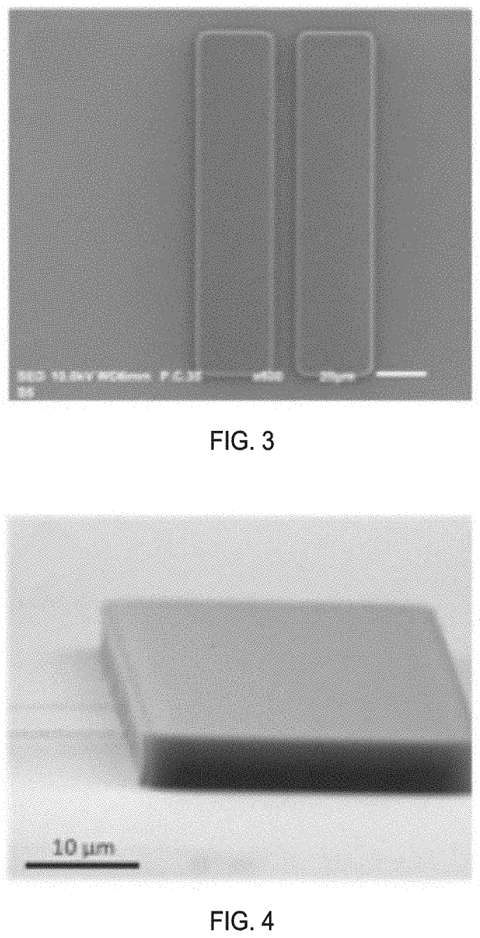

In an inventor experiment, a standard cleaning procedure was conducted prior to a lithography process. Then, a negative photoresist (AZ® nLOF 2035) was applied to pattern the LN samples with different cuts through a contact lithography process. Single crystal LN substrates were utilized with common orientations of 128YX, 128Y, 64Y, and thin film LN on silicon (Si) substrates with the orientations of X and Y. After patterning samples, the patterned samples were cleaned in an hydrogen (H) chloride (Cl) acid solution (HCl:H₂O, 1:3) and metallized in a metal evaporator. First, a hard mask with a composition having Ti, Al, and Cr was deposited. The process was followed by lift-off using a 1165 (n-methyl pyrrolidinone) solution. Then the samples were etched in a F₂-based in ICP. After etching, metal masks were removed using a diluted hydrogen fluoride (HF) solution. A scanning electron microscopy (SEM) was applied to inspect and analyze the samples through the processing. FIGS. 3 and 4 show top and side view SEM image of the patterned photoresist after lithography step, respectively. As seen, a perfect or near-perfect vertical sidewall was achieved to ensure formation of a high-quality metal mask after metallization process.

Identifying appropriate metal masks as hard mask for the etching purpose is an important, if not, crucial step for metal depositions. Some dry etch challenges such as redeposition of the mask material and the reaction products can be avoided using an appropriate metal for the processing. These challenges are more severe if the process needs to be designed to achieve deep structures on LN substrates as are desired for optical and photonic device applications.

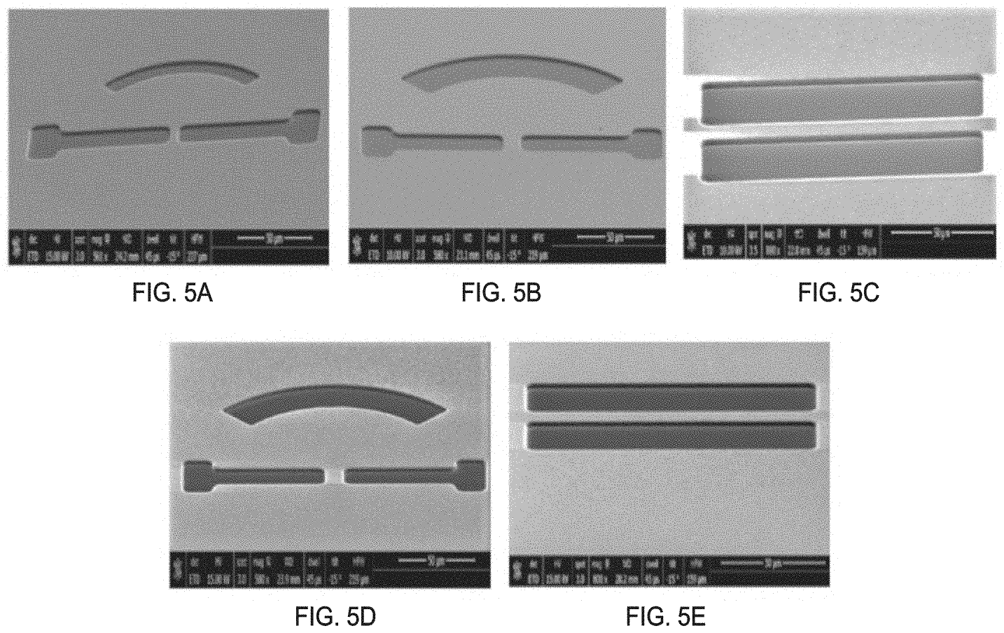

To find an example of an optimum metal mask for a deep dry etch on LN samples, different metal combinations were tried. These metal combinations included Ti/Al (20 nm/1.3 μm) and Ti/Al/Cr (20 nm/750 nm/750 nm). FIGS. 5A-5E compare the quality of the metallizations of Ti/Al on different LN cuts. FIG. 5A shows results using Ti/Al mask for single crystal LN substrate with 128YX orientation. FIG. 5B shows results using Ti/Al mask for single crystal LN substrate with 128Y orientation. FIG. 5C shows results using Ti/Al mask for single crystal LN substrate with 64Y orientation. FIG. 5D shows results using Ti/Al mask for X cut LN on silicon. FIG. 5E shows results using Ti/Al mask for Y cut LN on silicon.

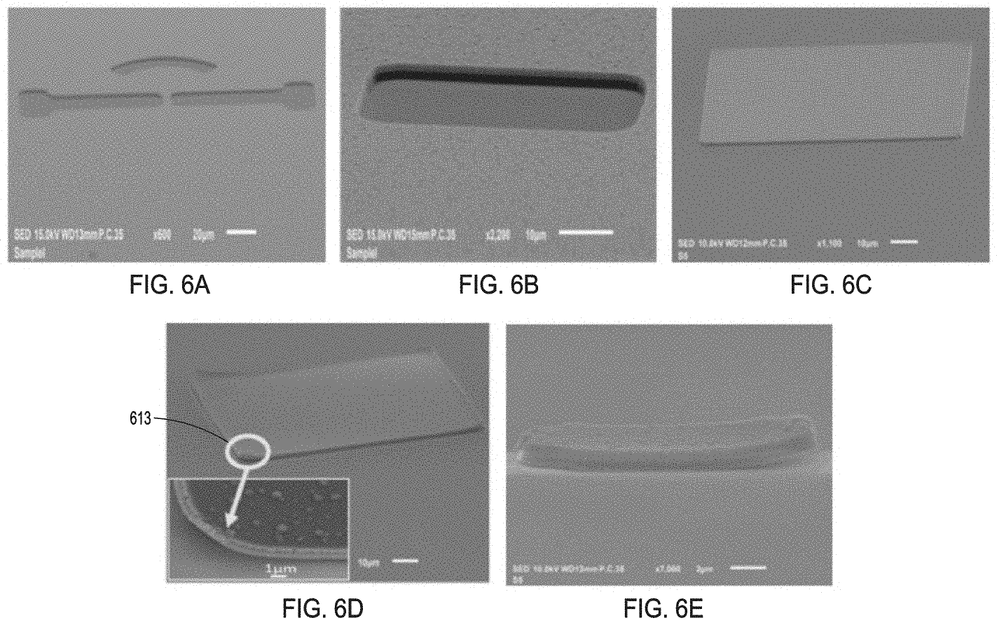

FIGS. 6A-6E compare the quality of the metallizations of Ti/Al/Cr on different LN cuts. FIG. 6A shows results using Ti/Al/Cr mask for single crystal LN substrate with 128YX orientation. FIG. 6B shows results using Ti/Al/Cr mask for single crystal LN substrate with 128Y orientation. FIG. 6C shows results using Ti/Al/Cr mask for single crystal LN substrate with 64Y orientation. FIG. 6D shows results using Ti/Al/Cr mask for X cut LN on silicon, including peeling off 613 of the metal mask at the edges of the microstructures. FIG. 6E shows results using Ti/Al/Cr mask for Y cut LN on silicon, where peeling off of portions of the metal mask also occurred. As seen in FIGS. 5A-5E, the Ti/Al stacks perfectly work perfectly or near-perfectly on all types of LN cuts, while the Ti/Al/Cr stacks did not work perfectly on the X cut LN and the Y cut LN on Si substrates as shown in FIGS. 6D-6E.

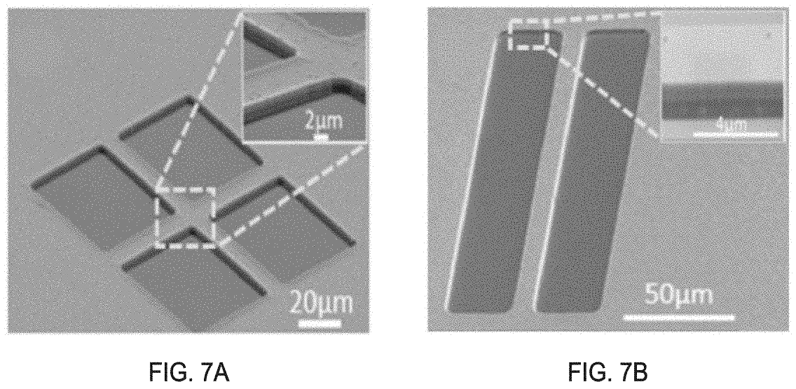

In order to explain this observation, it is hypothesized that both crystal orientation and the stress due to the transferring LN film on Si substrate play an important role on atomic bonding between metals and top surface of LN. Therefore, a surface treatment seems appropriate to improve the quality of the Ti/Al/Cr metal mask on X-cuts and Y-cuts. Researchers have performed similar treatment to engineer crystal properties of the LN using proton implantation. Here, a H₂-plasma treatment (H₂: 30 sccm, pressure: 15 mTorr, RF power: 150 W, ICP power: 300 W, DC bias: 53V) was employed in an ICP chamber prior to the lithography and metallization in order to imitate the effect of proton treatment on the LN substrate. FIG. 7A shows the metal mask quality on an X-cut after H₂-plasma treatment. FIG. 7B shows the metal mask quality on an Y-cut after H₂-plasma treatment. As seen in FIGS. 7A-7B, a remarkable improvement can be obtained using plasma treatment.

After obtaining high quality metal mask on LN cuts, the procedure included a plasma dry etch using F₂-based chemistry ICP. Previous research on etching LN revealed that formation of niobium fluoride (NbF₅) becomes volatile at temperatures around 200° C., while the lithium fluoride (LiF) byproducts will remain on the sidewalls and the surfaces that lower downs the etching rate of the LN.

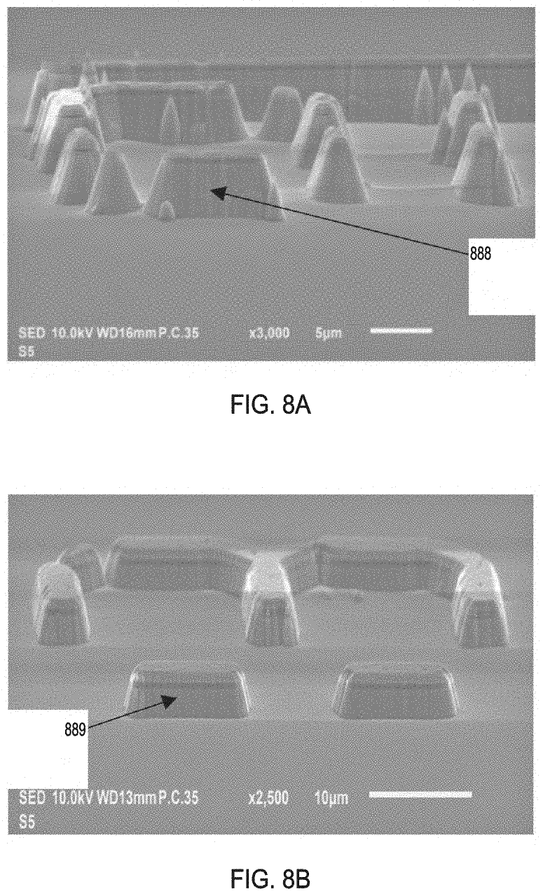

FIG. 8A shows an etched 128YX oriented LN 888 using trifluoromethane/argon (CHF₃/Ar) with a Ti/Al metal mask. FIG. 8B shows an etched 128YX oriented LN 889 using CHF₃/Ar gas with a Ti/Al/Cr metal mask. In an experiment by the inventors, a CHF₃/Ar plasma treatment (CHF₃: 30 sccm, Ar: 30 sccm, pressure: 5 mTorr, RF power: 100 W, ICP power: 150 W, DC bias: 40V) was used to achieve high selectivity and higher etch rate with a Cr-containing mask. As has been reported, Ar gas will increase the etching rate by enhancing the sputtering process during plasma etching. To prevent heating effect on etching process (due to low thermal conductance of LN), a periodic step process was implemented that included 20 mins etching followed by 4 mins cooling, where cooling refers to the plasma being off. Then, after each 1 hour of etching the samples were cleaned in standard cleaning solvent, which included acetone, isopropyl alcohol (IPA), deionized (DI) water, and a nitrogen (N₂) dry air blow.

It is clearly demonstrated that the etching profile with the Cr mask stacked on Al worked as a better mask since the surface roughness and redeposition underneath the sidewalls are omitted and also the verticality is nearly maintained as illustrated in FIG. 8B.

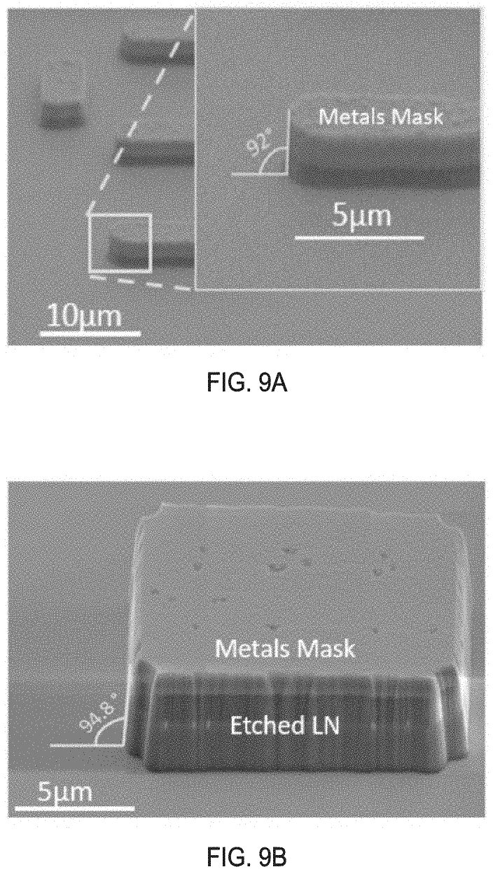

FIG. 9A shows verticality measurements for the features with metal masks. FIG. 9B shows verticality measurements for the features with and etched 128Y oriented lithium niobate with metal masks using CHF₃/Ar gases. It is observed from FIGS. 9A-9B that the verticality is nearly at a right angle for the metal masks defined on a microstructure. There is an approximately 3° offset for the etched LN with the stacks of metal masks, as shown in FIG. 9B. The offset may have arisen from lateral etching that may have happened during the plasma dry etching process. This result is good in terms of overall etching profile considering the surface roughness, verticality, and redeposition free sidewalls.

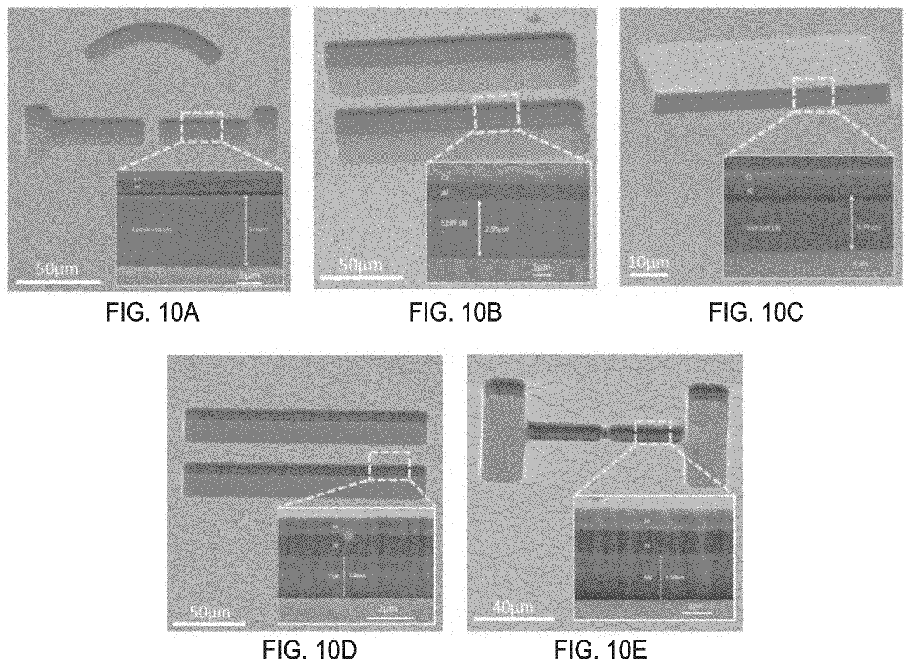

FIGS. 10A-10E show ICP etching of a micro-structure using CHF₃/Ar gases with Ti/Al/Cr metal masks. FIG. 10A shows results using CHF₃/Ar gases with a Ti/Al/Cr metal mask for a LN micro-structure with 128YX orientation. FIG. 10B shows results using CHF₃/Ar gases with a Ti/Al/Cr metal mask for a LN micro-structure with 128Y orientation. FIG. 10C shows results using CHF₃/Ar gases with a Ti/Al/Cr metal mask for a LN micro-structure with 64Y orientation. FIG. 10D shows results using CHF₃/Ar gases with a Ti/Al/Cr metal mask for a micro-structure for X cut LN on silicon. FIG. 10E shows results using CHF₃/Ar gases with a Ti/Al/Cr metal mask for a micro-structure with for Y cut LN on silicon. The etching profile for all the cuts appeared with high quality which can be clearly observed from FIGS. 10A-10E. As seen, X-cuts and Y-cuts after H₂-plasma treatment were also etched perfectly or near-perfectly consistent with the other cuts. Table 1 shows etching rates of different cuts of LN using CHF₃/Ar plasma.

TABLE 1

| | Etching Depth | Etch Rate of LN |
|---|---|---|
| Orientations | (μm) | (μm/h) |
| 128YX | 3.40 | 0.70 |
| 128Y | 2.95 | 0.65 |
| 64Y | 1.70 | 0.55 |
| X with H+ treatment | 1.40 | 0.70 |
| Y with H+ treatment | 1.50 | 0.75 |

Table 1 lists the etch rates and the obtained depths for all the cuts using CF₃/Ar (1:1) plasma dry etch. The etching rate may vary depending on the crystal orientations that may include properties of local neighborhood atoms, and may vary depending on the role of the dangling and surface bonds. As seen in Table 1, the etching rates are nearly the same, but 64Y and 128Y cuts present slightly lowering etch rate compared to the other cuts.

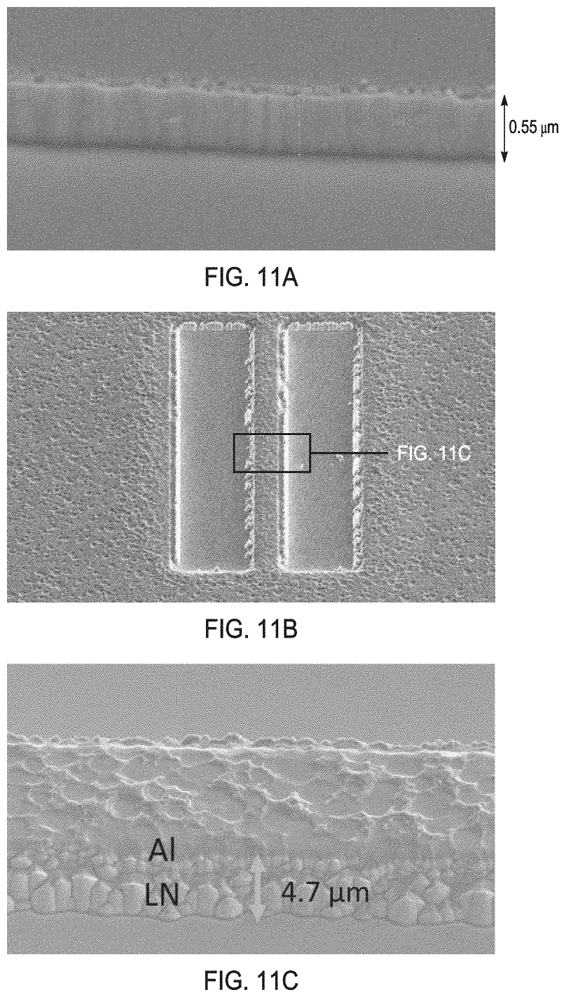

FIGS. 11A-11C through FIG. 23 illustrate application of processing procedures discussed herein. FIGS. 11A-11C show 128YX oriented LN dry etched with an Al mask using a sulfur hexafluoride (SF6) plasma. An etch rate of 0.335 μm/hr has been used.

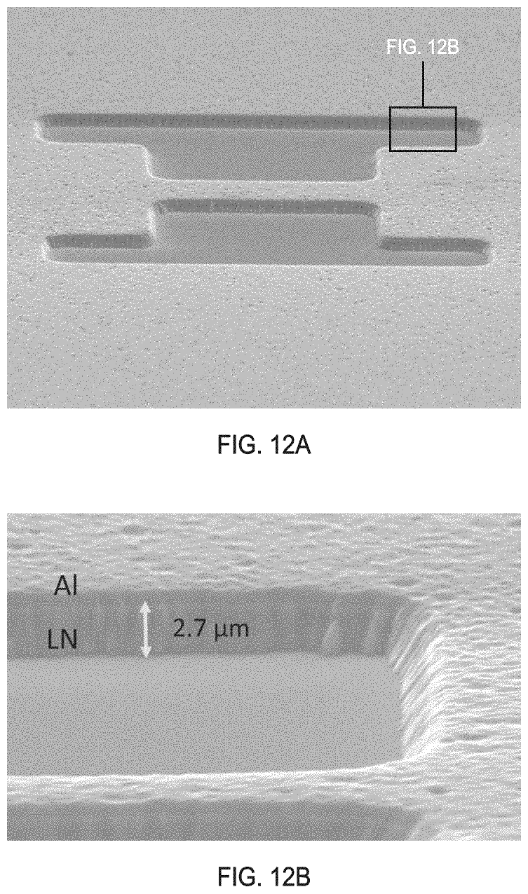

FIGS. 12A-12B show 128YX oriented LN dry etched with an Al mask using a CHF₃/Ar plasma. An etch rate of 0.810 μm/hr has been used. This is a higher rate than used with respect to FIGS. 11A-11C. This increased etching rate has resulted in less surface roughness. This increased etching rate has still resulted in redeposition and verticality.

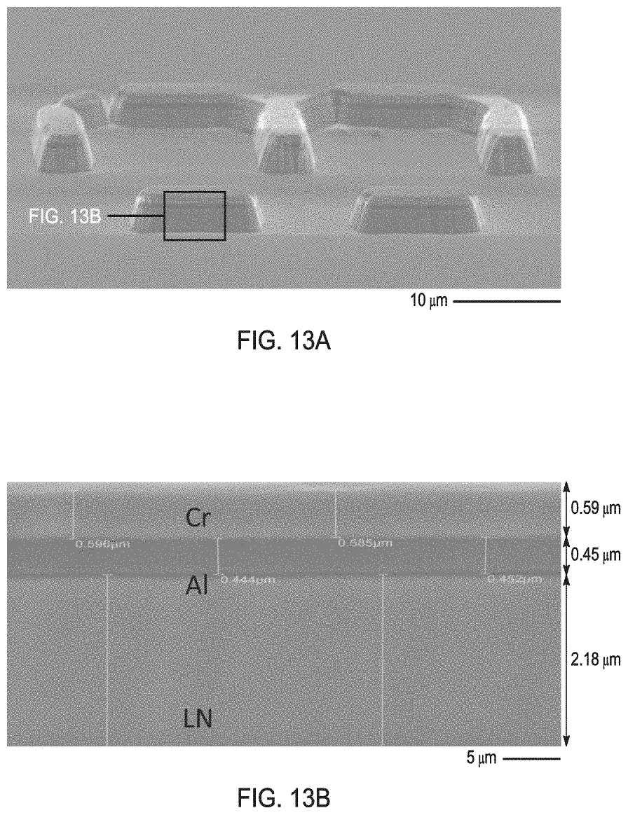

FIGS. 13A-13B show 128YX oriented LN dry etched with a Cr mask using a CHF₃/Ar plasma. An etch rate of 0.5 μm/hr has been used.

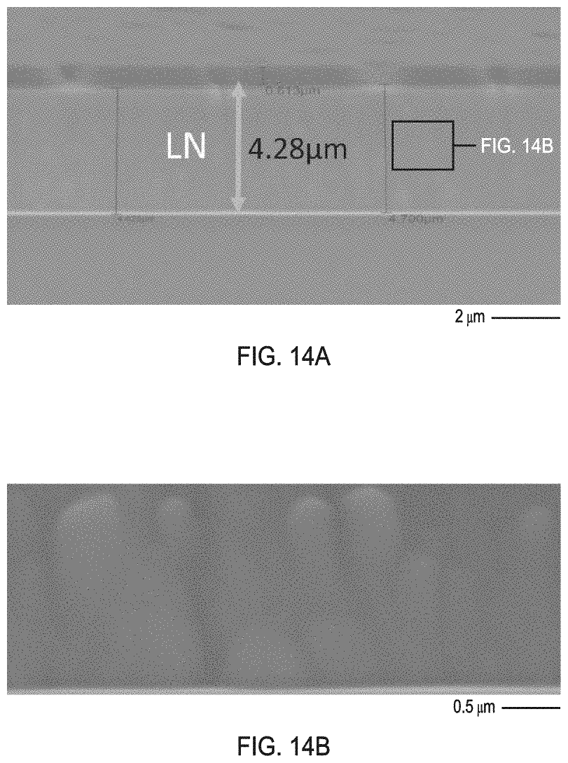

FIGS. 14A-14B show 128YX oriented LN dry etched with a Cr mask using a CHF₃/Ar plasma. A Cr layer has been depleted and Al has started to etch.

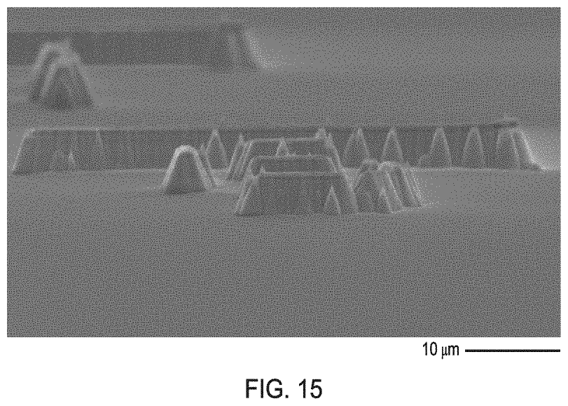

FIG. 15 shows re-deposition of LN by-products with an Al mask. A 128YX oriented LN has been dry etched with a Al mask using a CHF₃/Ar plasma. AlF₃ is not volatile and has a boiling point of 1290° C. CrF₄ is volatile and has a boiling point of 400° C.

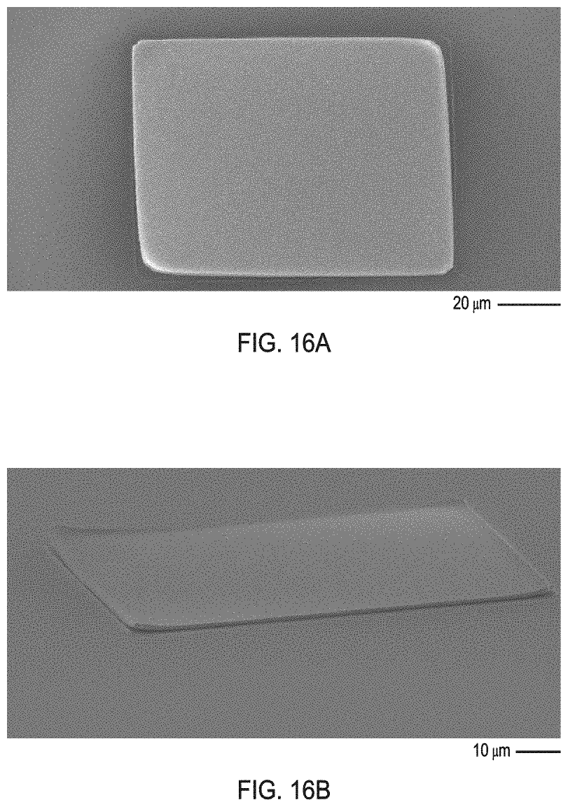

FIGS. 16A-16B show peeling off of metal films on X cut only LN on silicon. FIG. 16A is a top view of lift off. FIG. 16B is a side view of lift off.

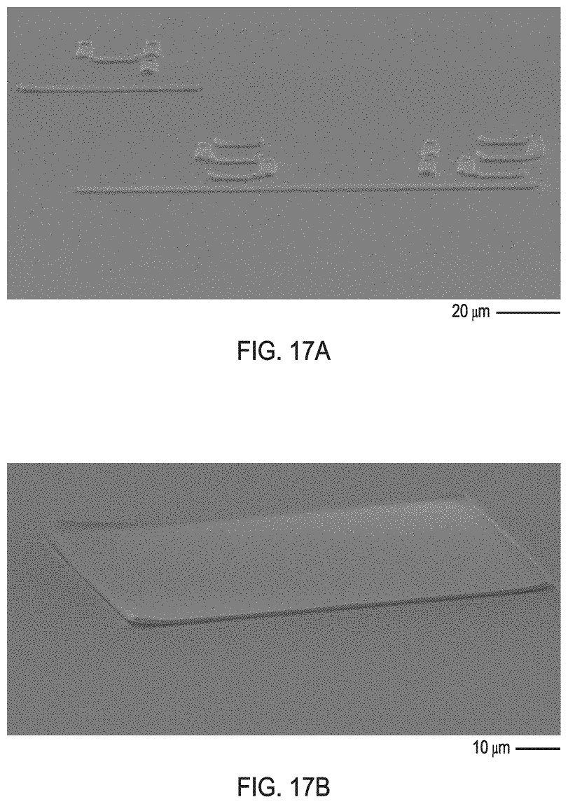

FIGS. 17A-17B show peeling off metal films on Y cut only LN on silicon. FIG. 17A is a top view of lift off. FIG. 17B is a side view of lift off.

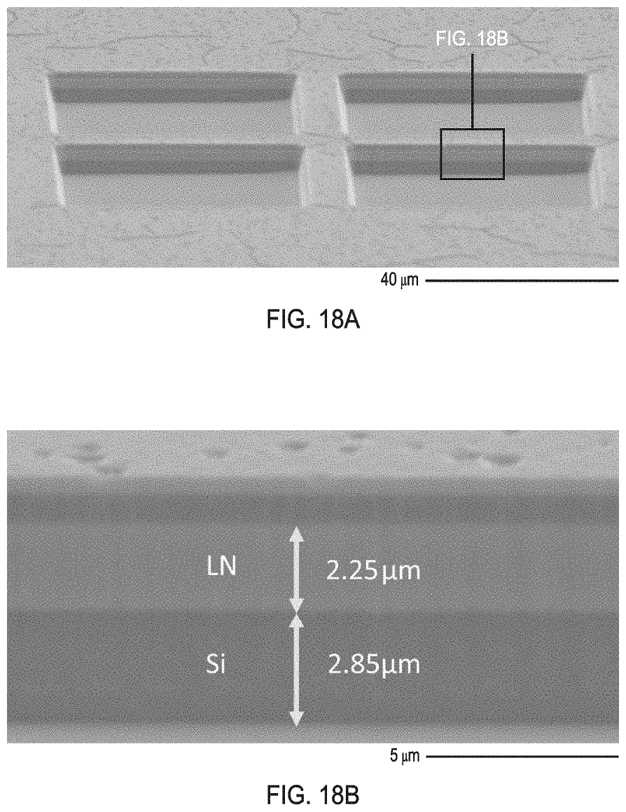

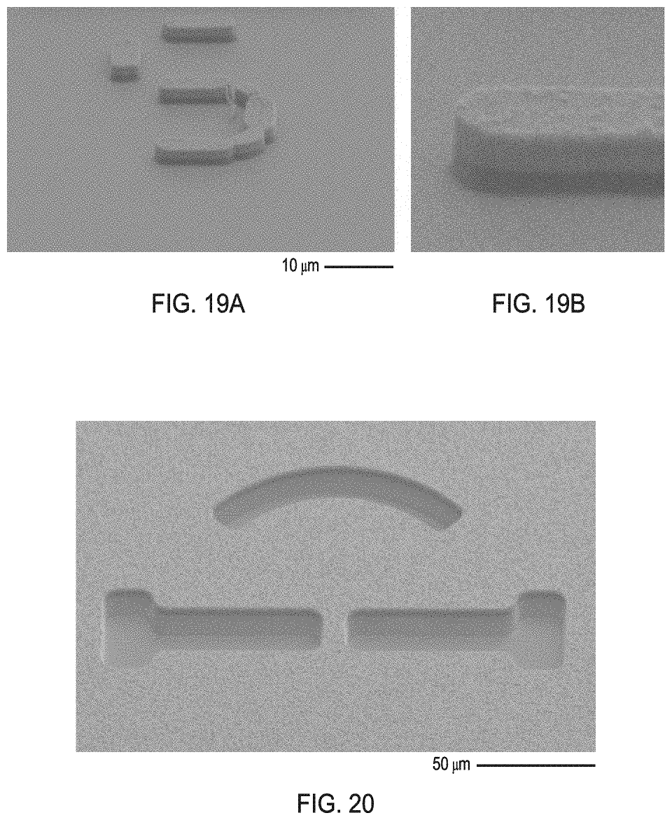

FIGS. 18A-18B and FIGS. 19A-19B show results with respect to plasma treatment and etching. Plasma treatment improves the bonding process. The plasma treatment can increase surface energy and can remove contaminants.

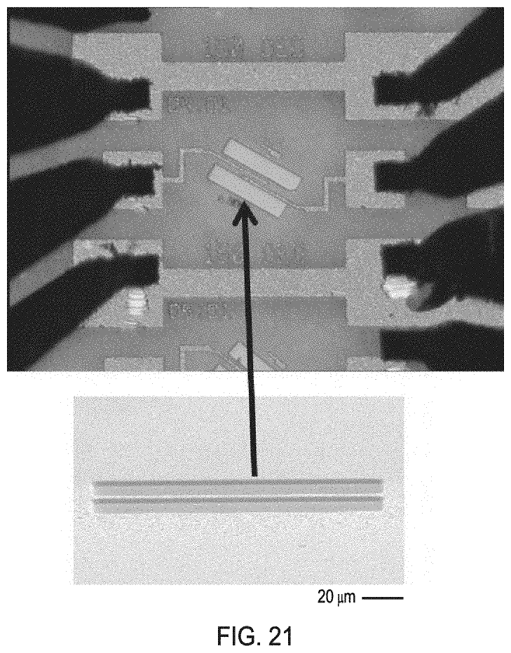

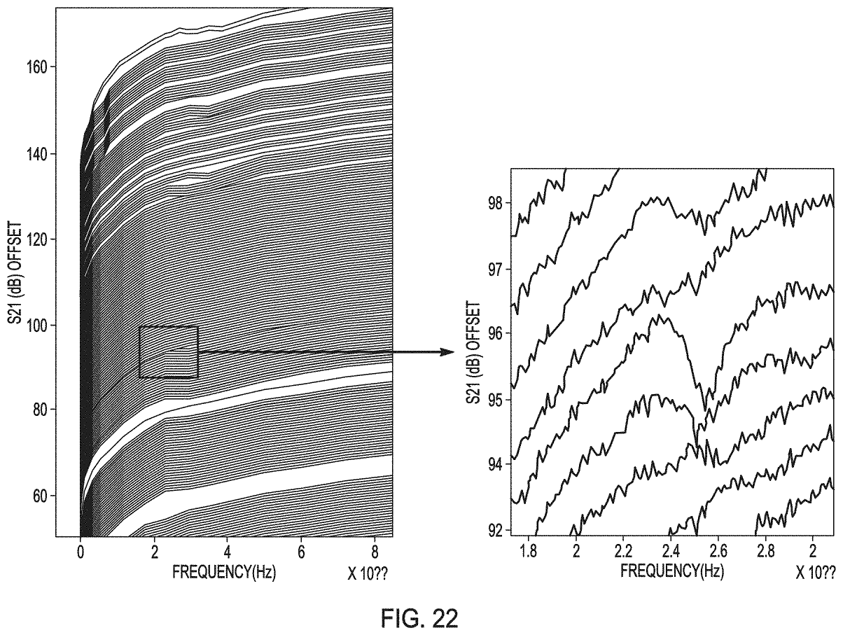

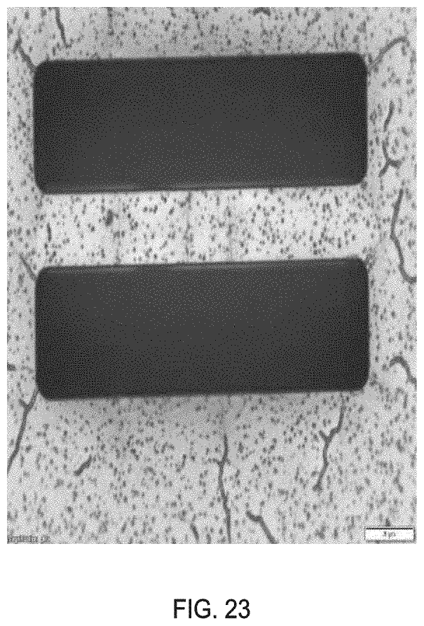

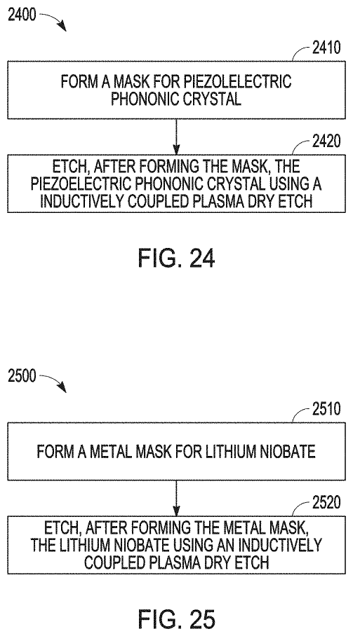

FIGS. 20-23 illustrate device fabrication, characterization, and release of LN. FIG. 20 shows etched LN. FIG. 21 represents images of a device having etched LN. FIG. 22 shows radio frequency testing for a one micron etched LN. FIG. 23 shows a partial release structure. Enhanced fabrication and processing have been disclosed that can realize good metal masks and etching chemistry to obtain vertical sidewalls omitting redeposition problems.

An optimum ICP dry etch process to obtain a deep etching profile in LN substrate with minimum roughness and vertical sidewalls has been disclosed. Combination of CHF₃/Ar (1:1) gases were used to etch all LN substrates. The plasma etching characteristics of different orientations of LN samples were studied under various metal masks. The stack of Ti/Al/Cr metals found to be the best mask material for all cuts i.e., 128YX, 128Y, 64Y, X-, and Y-cuts as it removed all the redeposition and micro-masking issues during the dry etch process. However, to achieve the same quality of metal mask, X-cut and Y-cut samples were treated with H₂-Plasma. It is assumed that the plasma treatment will mitigate surface stress on the transferred LN film due to the Si substrate and also can modify the surface structures by replacing Li-ion with protons. Likewise, periodic interruptions were included in a plasma dry etch recipe followed by a chemical cleaning between each cycle to avoid thermal effect and minimize byproduct redeposition during the long etching process. Microstructures with etch depths as deep as 3.4 μm were achieved using this method with a smooth sidewall and perfect verticality, which is promising for fabrication of optical devices where high-aspect ratio structures are required.

Processing and examining LN structures, as discussed herein, can lead to understanding the stress-strain effect on different cuts of LN. Such processing techniques can lead to building a multilayer phononic crystal structure. LN on Al₂O₃ ca be used followed by lapping to enable repeated epitaxial growth to build up a phononic structure. Compositions such as GaN may possibly be used. Such processing techniques may be used in the fabrication of resonators and testing and characterization of opto-mechanical devices.

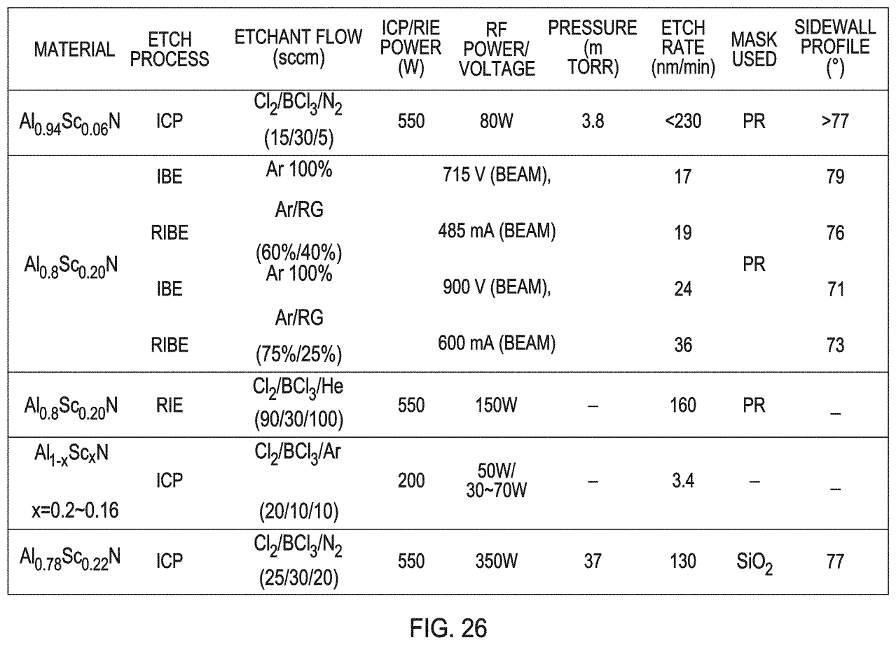

FIG. 24 is a flow diagram of features of an embodiment of an example method 2400 of processing a piezoelectric material. At 2410, a mask is formed for a piezoelectric material on a substrate. The mask can be selected based on the piezoelectric material to be processed. At 2420, after forming the mask, the piezoelectric material is etched using an ICP dry etch. The ICP etching forms a patterned structure in the piezoelectric material.

Variations of method 2400 or methods similar to method 2400 can include a number of different embodiments that may be combined depending on the application of such methods and/or the architecture of systems including a piezoelectric material in which such methods are implemented. Such variations can include forming the mask as a hard mask and applying a hydrogen-plasma treatment to the hard mask prior to using the inductively coupled plasma dry etch. The hard mask can be a metal mask.

Variations of method 2400 or methods similar to method 2400 can include the etching being performed by using periodic interruptions to the etching followed by a chemical cleaning between each cycle of the etching. Variations can include forming the patterned structure in the piezoelectric material having vertical sidewalls. The vertical sidewalls can deviate from ninety degrees by five degrees or less. Variations can include the piezoelectric material to include lithium niobate. The lithium niobate can be structured on a silicon substrate.

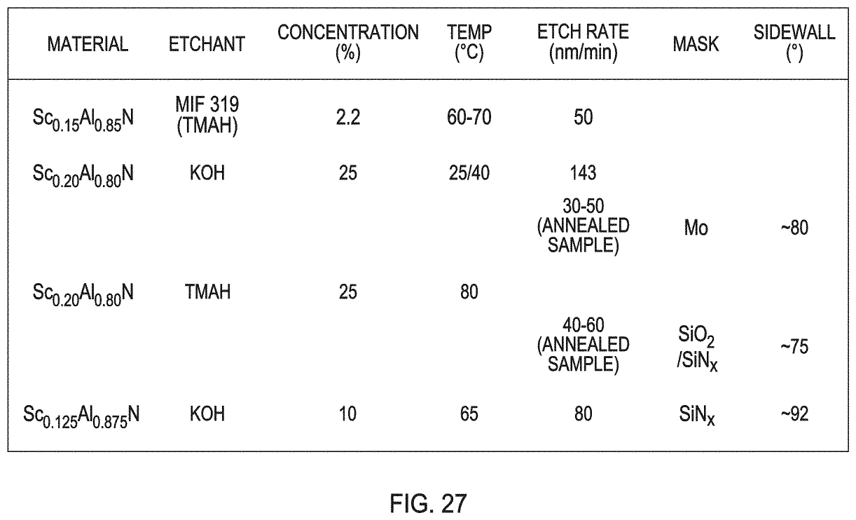

FIG. 25 is a flow diagram of features of an embodiment of an example method 2500 of processing lithium niobate. At 2510, a metal mask is formed for lithium niobate on a substrate. At 2520, after forming the metal mask, the lithium niobate is etched using an ICP dry etch. The ICP etching forms a patterned structure in the lithium niobate. The ICP etching of the lithium niobate can be performed in fabricating an apparatus as a component of a system, such as, but not limited to, a scalable radio frequency micro-electromechanical system having the lithium niobate as a component.

Variations of method 2500 or methods similar to method 2500 can include a number of different embodiments that may be combined depending on the application of such methods and/or the architecture of systems including a lithium niobate crystal in which such methods are implemented. Such variations can include the metal mask having a composition of one or more of titanium, aluminum, or chromium. Such variations can include the ICP dry etch using one or more fluoride-based chemistries. The one or more fluoride-based chemistries can include one or more of sulfur hexafluoride or trifluoromethane.

Variations of method 2500 or methods similar to method 2500 can include applying a hydrogen-plasma treatment to the metal mask prior to applying the inductively coupled plasma dry etch. Variations can include using periodic interruptions to the etching followed by a chemical cleaning between each cycle of the etching.

Variations of method 2500 or methods similar to method 2500 can include forming the patterned structure in the lithium niobate with the lithium niobate forming the patterned structure having vertical sidewalls. The vertical sidewalls can deviate from ninety degrees by five degrees or less.

Variations of method 2500 or methods similar to method 2500 can include forming the metal mask by spin coating a photoresist on the lithium niobate and forming a pattern in the photoresist using photolithography. A metallization can be formed according to the pattern and the photoresist of the pattern can be removed.

Wide bandgap, enhanced piezoelectric responses, high electromechanical coupling, and low dielectric permittivity are some of the outstanding properties that have made scandium aluminum nitride (ScₓAl₁₋ₓN) a promising material in multiple applications. One of the major challenges in device fabrication including ScₓAl₁₋ₓN is its resistivity to etch, specifically with the higher scandium concentration. Herein, a developed experimental approach of a wet etching process by using tetramethyl ammonium hydroxide (TMAH) followed by high temperature annealing is disclosed. This approach can maintain uniformity of etching in lower as well as higher scandium concentrations. In this disclosure, presentation is made of experimental results of etching approximately 730 nm of ScₓAl₁₋ₓN (x=12.5%, 20%, 40%) thin films, where it can be observed that the etching rate reduces with the increase of scandium content. Nevertheless, in this work by the inventors, sidewall verticality (85°˜90°) for all the concentrations has been successfully maintained in experiments. As shown by the experimental outcomes, the etching procedure can be advantageous in the fabrication of acoustic, photonic, and piezoelectric devices.

Group III-V materials are getting notable attraction for their diverse applications in MEMS, piezoelectric transducers, resonators, RF acoustic devices. Due to some of its promising qualities and simplicity of process integration, aluminum nitride (AlN) is widely employed in piezoelectric MEMS devices. AlN can be doped with other metals to enrich its piezoelectric properties and ensure more efficient coupling, which leads to the success of ScₓAl₁₋ₓN based integrated photonic circuits and optical waveguides. Previous researchers have used first-principles analysis to determine that the wurtzite structure of ScₓAl₁₋ₓN(Sc-IIIA-N) alloys can be fabricated, and it might have a more significant piezoelectric coefficient value in comparison with AlN. This more significant piezoelectric coefficient value was proved that by measuring co-sputtered ScₓAl₁₋ₓN films, indicating a peak coefficient of 27.6 pC/N and a higher piezoelectric response compared to AlN. Furthermore, according to the experiments of other researchers, the electromechanical coupling coefficient (kₜ²) value of scandium doped AlN can be improved by up to 15%. As noted in the literature, utilizing ScₓAl₁₋ₓN thin film with increased scandium concentration offers a great opportunity for the fabrication of high-frequency and wideband acoustic wave filters. However, the ScₓAl₁₋ₓN thin film becomes increasingly resistant to etching as the scandium concentration (x) rises, especially when using reactive ion etching (RIE) or inductively coupled plasma (ICP) etching. In the past two decades, substantial research has been performed on ScₓAl₁₋ₓN to understand its material features, growth, characterization, how different etching can be used for device manufacture.

Like other group III-V materials, ScₓAl₁₋ₓN can be etched by dry or wet etching techniques. One of the known dry etching approaches is ion beam etching, which can be physical or chemical and can result in etched surfaces for ScₓAl₁₋ₓN with a smooth surface and a suitable etch rate. Table 1 lists some outcomes of dry etching attempts of ScₓAl₁₋ₓN considering sidewall verticality and etch rate. Researchers have tried ICP etching with thick S1818 photoresist (PR) as an etch mask with promising results, in which they demonstrated how RF power might control the sample's plasma etching energy, and demonstrated that the energy of the Cl₂/boron trichloride (BCl₃)/N₂ plasma enhances the sidewall angle of Sc_{0.06}Al_{0.94}N sample etching. Other researchers have demonstrated that the reactive ion beam etching (RIBE) process of ScₓAl₁₋ₓN etching is superior to ion beam etching (IBE) in terms of etching rate, selectivity, sidewall angle (73°), and a smooth surface free of roughness. The ScₓAl₁₋ₓN etching rate and selectivity degrade when the identical beam parameters are used without the reactive gas. On the other hand, other researchers presented the design, manufacture, and characterization of Sc_{0.20}Al_{0.80}N thin films based on piezoelectric micromachined ultrasound transducers (PMUTs) using RIE as an etching process, where these researchers claimed that the etched layer has good verticality and concluded that increasing the scandium concentration would enhance PMUT performance. Other researchers attempted ICP etching using Ar rather than the more commonly used nitrogen, in which their etch rate is comparably lower. Furthermore, other researchers successfully fabricated a lamb wave resonator with a quality factor of around 1000 with Sc_{0.22}Al_{0.78}N, in which they have demonstrated a reasonable etching rate (130 nm/min), and promising verticality (77°). They also concluded that the primary reactive etching gas Cl₂ increases the anisotropy of the etching process. However, as reported in other publications, as the dry etching process is mainly Cl₂/BCl₃ based, performing dry etching of ScₓAl₁₋ₓN is an ineffective process due to ScCl₃'s poor volatility. In other reports, it is noted that it takes more etching power and ion bombardment to get the etching rate back to a considerable level. Moreover, other researchers have reported that it was found that excessive etching into the bottom layer might have a risk concern and a lower etching rate as well as high-power consumption are the fundamental causes of poor selectivity to various mask materials, which has accelerated the wet etching trials in the research community.

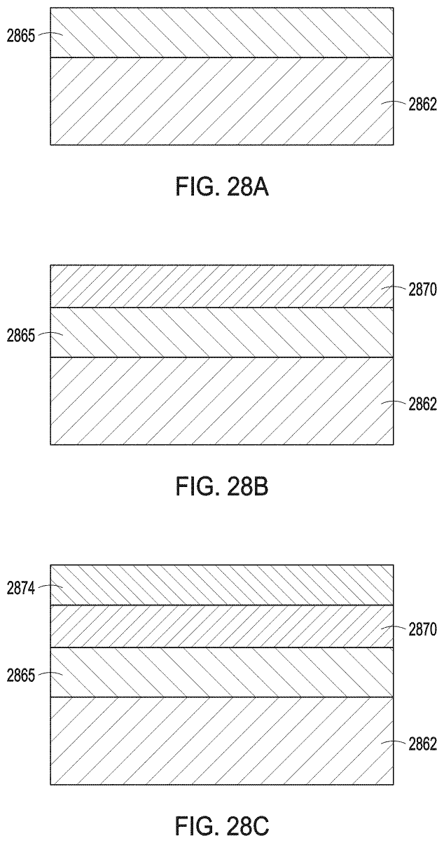

Due to the different experimental conditions, it is not easy to draw any conclusive comment about the wet etching from prior research works; nonetheless, some older experimental outcomes are presented here, demonstrating promising results as shown in the table of FIG. 26. The etching rate of Sc_{0.15}Al_{0.85}N was found to be approximately 50 nm/min (at 60-70° C.) with MIF-319 developer that generally contains 2-5%% TMAH. Another work demonstrated that employing 25% KOH 80° C., a 500 nm Sc_{0.36}Al_{0.64}N layer could be etched in only 15 s, which indicates KOH as a promising etchant. Several authors highlighted the biggest issue with wet etching is lateral etching behind the mask. Wet etching becomes a highly appealing choice if the lateral etching that occurs throughout the process is not an issue or if it can be minimized to acceptable levels. Another notable observation from previous work is that alkaline etchants outperform acidic etchants in terms of side wall roughness and etching rate. In such previous work, different etch masks (molybdenum (Mo)/SiO₂/SiNₓ) with 25% TMAH at 80° C. were used and it was concluded that the mask did not make any difference in the etching results. In a recent work, vertical etching of Sc_{0.125}Al_{0.875}N has been demonstrated by using 10% KOH at the temperature of 65° C. In this recent work, the researchers have successfully etched down a 800 nm thick Sc_{0.125}Al_{0.875}N layer, but the process encountered a significant amount of lateral etching (approx. 395 nm). Also, the process was not suitable for etching ScₓAl₁₋ₓN with higher concentrations, as it could not provide good vertical sidewalls.

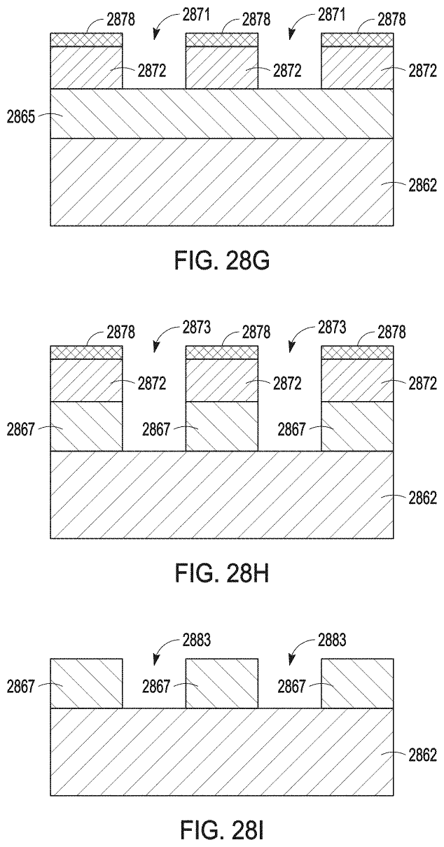

In this disclosure, a wet etching process using a TMAH solution for etching ScₓAl₁₋ₓN thin films is presented, introducing an intermediary thermal annealing process, which can be demonstrated using the procedures of FIGS. 28A-28I. This wet etching process can be demonstrated for ScₓAl₁₋ₓN thin films with x=12.5%, 20%, and 40%. The intermediary thermal annealing process can be realized by an intermediary thermal annealing process at 650° C. in a nitrogen atmosphere. This experimental approach and etching results demonstrate a “Universal Method” to etching ScₓAl₁₋ₓN with a state-of-art sidewalls verticality between 85° C. and 90° C.

FIGS. 28A-28I illustrates features of etch processing for thin films having a piezoelectric material. FIG. 28A shows a structure after a piezoelectric material 2865 has been formed on a wafer 2862. Piezoelectric material 2865 can be ScₓAl₁₋ₓN and wafer 2862 can be a Si wafer. FIG. 28B shows the structure of FIG. 28A after further processing. A mask material 2870 has been formed on piezoelectric material 2865. Mask material 2870 can be SiO₂ or silicon oxide of another stoichiometry. FIG. 28C shows the structure of FIG. 28B after further processing. A masking material 2874 has been formed on mask material 2870. Masking material 2874 can be a photoresist.

FIG. 28D shows the structure of FIG. 28C after further processing. Masking material 2874 has been subjected to application of lithography forming a pattern of masking material 2875 on mask material 2870, in which portions of mask material 2870 has been exposed. Masking material 2875 has the composition of masking material 2874. FIG. 28E shows the structure of FIG. 28D after further processing. A masking material 2877 has been formed on masking material 2875 and on the exposed portions of mask material 2870. Masking material 2877 can be a metal. For example, masking material 2877 can be Ni. FIG. 28F shows the structure of FIG. 28E after further processing. Masking material 2877 on masking material 2875 and masking material 2875 have been removed, forming openings 2869 among a pattern of masking material 2878, where patterned masking material 2878 is masking material 2877 subjected to the removal procedure. With masking material 2877 being Ni, the removal procedure can be a lift-off procedure of the Ni masking material 2877.

FIG. 28G shows the structure of FIG. 28F after further processing. High temperature annealing has been applied followed by ICP etching, removing portions of mask material 2870 below openings 2869. The removal has increased openings 2869 to openings 2871, exposing portions of piezoelectric material 2865. Mask material 2870 has been converted to a pattern of mask material 2872 having the composition of mask material 2870. FIG. 28H shows the structure of FIG. 28G after further processing. Portions of piezoelectric material 2865 under openings 2871 have been removed, exposing portions of wafer 2862 and expanding openings 2871 to openings 2873. Removal of portions of piezoelectric material 2865 can be conducted by a TMAH wet etching of piezoelectric material 2865. FIG. 28I shows the structure of FIG. 28H after further processing. The hard mask of patterned masking material 2878 on patterned mask material 2872 has been removed, leaving a pattern of piezoelectric material 2867 from original piezoelectric material 2865 separated by openings 2883. Piezoelectric material 2867 can have substantially vertical sidewalls at the openings 2883.

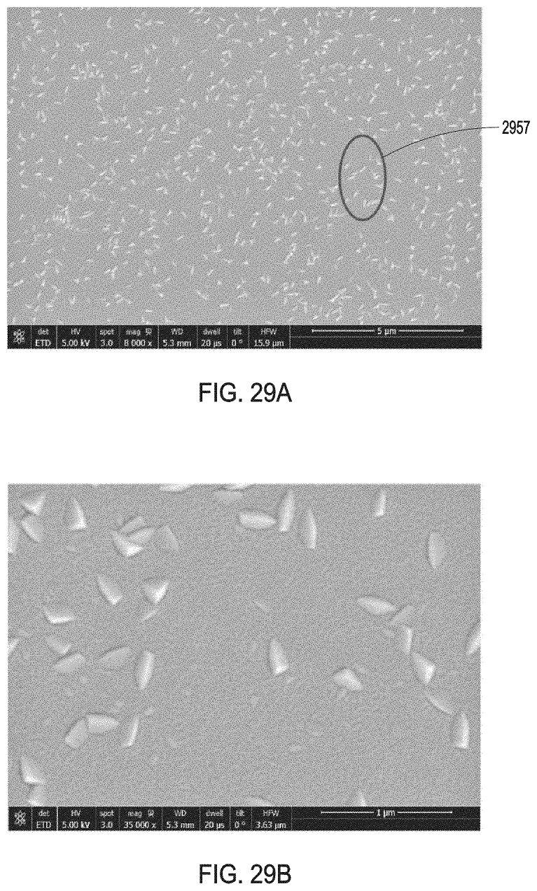

Experiments of a wet process, disclosed herein, included thin film deposition of SiO₂, application of lithography, preparation of a nickel (Ni) mask and lift-off of the Ni mask, high temperature annealing, ICP etching of the SiO₂ layer, and TMAH wet etching. ScₓAl₁₋ₓN samples for the experiments were grown sputter-coated in a physical vapor deposition system. With this method, the ScₓAl₁₋ₓN thin film contains abnormally oriented grains (AOG) which makes the surface highly rough, as can be seen in FIGS. 29A-29B and prevents uniform patterning over ScₓAl₁₋ₓN for the hard mask to be used to define the features to be etched. FIGS. 29A-29B show SEM images of a rough Sc_{0.20}Al_{0.40}N surface with abnormally oriented grains (AOG) highlighted as region 2957. Subsequently, a SiO₂ thin film was deposited over ScₓAl₁₋ₓN. Before the ScₓAl₁₋ₓN deposition, the samples were cleaned adequately with acetone, isopropyl alcohol (IPA), and diluted (DI) water. Many researchers have used piranha cleaning solution (mixture of H₂SO₄ and H₂O₂); however, this cleaning solution is not recommended, especially for 40% scandium doped AlN, as the inventors have found in experimentation that piranha also etches the scandium layer. After cleaning, the samples were dried up with a nitrogen gun. A thin layer of SiO₂ was deposited using a CHA Mark-40 dielectric evaporator, where the SiO₂ will eventually work as a hard mask for etching the ScₓAl₁₋ₓN layer. The base chamber pressure was 1.8×10⁻⁷ Torr, where the filament current and beam current were maintained at 0.36 A and approximately between 6.3 and 7.5 mA, respectively, during the deposition process. O₂ backflow (40 sccm) was conducted at the pressure level of 2.5×10⁻⁵ Torr. SiO₂ hard masks of 330 nm and 1 μm thick were used for ScₓAl₁₋ₓN layer etching. The experiments demonstrate that the etching quality does not depend upon the mask layer thickness. In total, twenty-four samples were prepared for the further processing.

After the silicon-dioxide deposition, lithography was conducted using a MLA 150 Advanced Maskless Aligner from Heidelberg Instruments. During the process, AZ5214E photoresist (PR) was used at 5000 rpm in the spin coating process, which created a thickness of approximately 1.2 to 1.4 microns. The samples were pre-baked at 110° C. for 4 minutes and then exposed with 405 nm UV light at 135 mJ/cm². Finally, the samples were developed in a AZMIF-300 for approximately 45 to 50 seconds and rinsed in diluted water.

With SiO₂ utilized as the mask layer for ScₓAl₁₋ₓN etching, another mask layer was used to etch SiO₂ layer first. An e-beam evaporation was used to deposit 100 nm of Ni, which will serve as a mask to etch SiO₂ layer. During the Ni-metallization process, the base chamber pressure and evaporation pressure were maintained at 3.3×10⁻⁷ Torr and 1.2×10⁻⁶ Torr, respectively. The deposition process was performed at 0.5 Å/s to ensure a smooth Ni surface. Afterwards, the deposited samples were soaked in acetone solution for 15 mins for lifting off the photoresist and opening space for SiO₂ layer etching. At a later processing, all the samples were rinsed with acetone, IPA, and DI water.

An ICP etching method was used to etch down the SiO₂ layer. Initially, a chamber cleaning process was performed for 10 mins, where 50 sccm of O₂ was used with 30 mTorr chamber pressure. Later, a fluorine-based ICP process was performed for 1 min 50 s. CHF₃ (45 sccm) and O₂ (5 sccm) gases were used as the primary etchants during the process, where ICP, RF power, and chamber pressure were set at 400 W, 100 W, and 5 mTorr, respectively. There will be some Ni still existing after ICP process, but this is not significant as it will be removed later during the wet etching and HF cleaning process.

Generally, during any ICP process, the ions generated by the plasma bombardment and the etched surface transfer kinetic energy. Moreover, it creates significant surface damage, in which lateral etching occurs for further etching. As a consequence, an intermediary process before ScₓAl₁₋ₓN etching, is implemented that can remove the impurities of the grains as well as repair the damaged ions. Researchers have demonstrated that, high temperature thermal annealing process could be a prospective solution to the challenge. Thus, after the SiO₂ mask has been defined, the samples were placed in a high-temperature annealing furnace chamber in a nitrogen atmosphere and annealed for 1 hr at 650° C. Researchers have demonstrated that there is a possibility of damaging the ScₓAl₁₋ₓN during annealing process due to the high compressive stress produced by the annealing, which might be linked with the lattice parameters of the corresponding ScₓAl₁₋ₓN film. Thus, in the experiments disclosed herein, a slow temperature gradient of 20° C./min was used for ramping up the process and cooling down the samples, as well as using a minimal nitrogen gas flow of approximately 40 sccm to 45 sccm to ensure the mechanical stability of the samples.

The recent success of KOH based wet etching process of ScₓAl₁₋ₓN (x=12.5%) results in poor verticality of approximately 55′ to about 65′ for Sc_{0.20}Al_{0.80}N, and Sc_{0.40}Al_{0.60}N, while on the other hand, other researchers have demonstrated that TMAH could be used as a wet chemical etchant for Sc_{0.20}Al_{0.80}N. In the experiments disclosed herein, 25% concentrated TMAH (TMAH:Water in 1:3 ratio) solution was used at approximately 78° C. to 82° C. to etch ScₓAl₁₋ₓN (x=12.5%, 20%, 40%) layer. In these experiments, the etching rate of Sc_{0.125}Al_{0.875}N, Sc_{0.20}Al_{0.80}N, and Sc_{0.40}Al_{0.60}N was found to be approximately 365 nm/min, 243 nm/min, and 81 nm/min, respectively. It was observed that the etching rate is significantly lower compared to the etching rate presented for AlN of 1500 nm/min in the literatures. Similar to other group III-V materials, ScₓAl₁₋ₓN is expected to form oxides compound while reacting with TMAH [N(CH₃)₄⁺OH⁻]. During the wet etch process of ScₓAl₁₋ₓN, when it mixes with the TMAH solution, nitride forms separately by Al and Sc, and thereafter, AlN and ScN react, where, generally, oxides and amphoteric substance are produced. The following chemical reactions are expected to happen during the wet etching process disclosed herein:

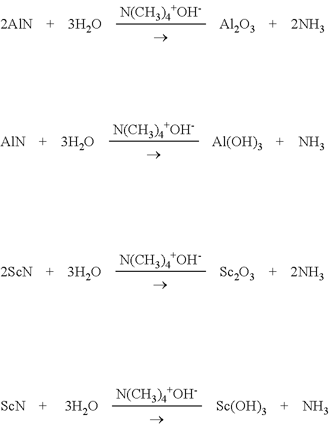

The formation of the scandium hydroxide residues occurs at a temperature of less than 85° C., and it slows down the etching process of ScₓAl₁₋ₓN. During the chemical reaction process, other components such as CH₄, NO, and NO₂ can be formed as well, usually at higher temperatures greater than 300° C. Thus, in the experiments disclosed herein, the temperature of the TMAH solution was kept at 80° C. during the etching process in order to have fine control of the etching rates. Hydroxides that eventually remain on the sample as shown in FIG. 29A can be removed using a HF solution with DI water.

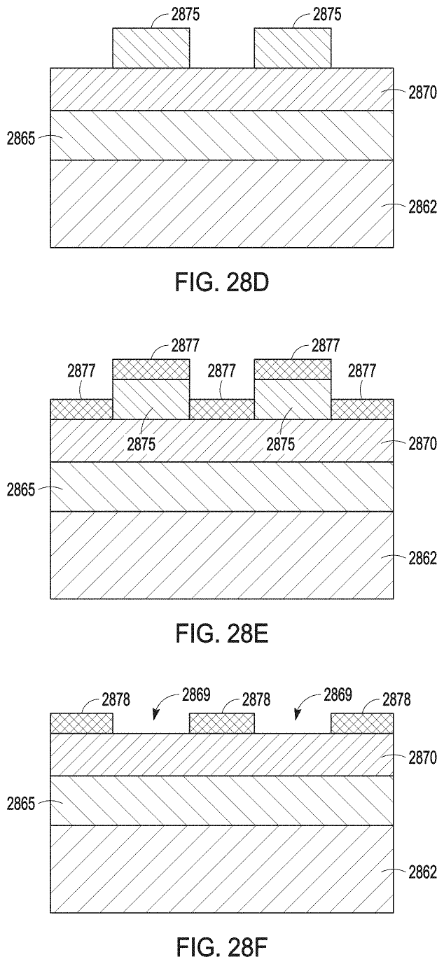

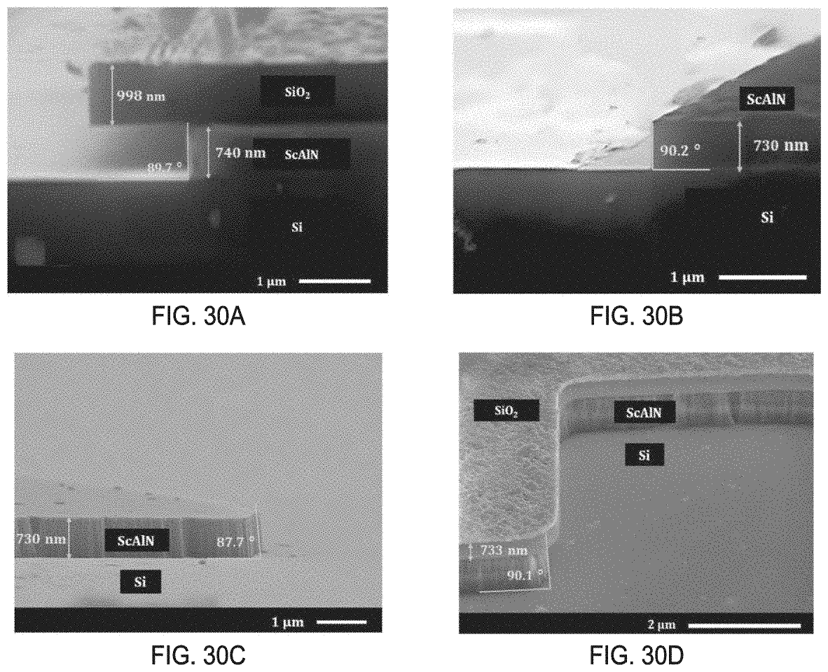

The experiments and processing approaches herein developed a process to etch ScₓAl₁₋ₓN layer with a vertical sidewall that will be valid for a wide range of concentrations of scandium into AlN. In several research publications, it is reported that the etch rate decreases with the increase of scandium concentration, and the verticality of the side walls decreases. Several etching processes shown in the table of FIGS. 26 and 27 have been developed to date to overcome this issue for different scandium concentrations. Moreover, it seems that, for scandium concentration larger than 25%, no state-of-art etching process has been reported that allows vertical sidewalls better than 70°. The work herein included determining a suitable etchant that can etch ScₓAl₁₋ₓN with a wide range of scandium concentrations. As is known, in general, alkaline etchants perform better compared to acidic etchants. Since TMAH is an alkaline etchant widely used in silicon etching processes industrially, experiments disclosed herein started to tune the concentration and temperature for the TMAH wet etching process. Due to the nature of the ScₓAl₁₋ₓN films, which contain several AOGs, the films are also etched laterally. Researchers demonstrated the reason behind the dependency of lateral etch with the AOGs, where it was shown that the AOGs are slanted from the normal direction compared to the actual film surface and do not precisely nucleate from the bottom of the film. This scenario is known as “undercut etch”, which is illustrated in FIG. 30A. The SiO₂ mask is resistant to the TMAH, and it looks suspended on top of the ScₓAl₁₋ₓN layer. Thus, in the experiments disclosed herein, high-temperature annealing providing thermal diffusion was performed in a nitrogen atmosphere to recover the surface damage by minimizing the effect of ion bombardment. It has been demonstrated in the literature that annealing is expected to increase the piezoelectric properties of the samples. In addition to this, AOGs generated during the growth process; increases etch resistivity, which is also one of the key reasons for poor dry etch results and non-uniform etching. See the table of FIG. 26. It has been reported in the literature that if the number of AOGs increase, cones formed during the etching process will be increased as well, which will eventually increase the possibility of device failure.

Selecting a suitable hard mask was another challenge. Researchers demonstrated that Mo/SiO₂/SiNₓ could be used as etching mask for TMAH-based etching of ScₓAl₁₋ₓN, and it does not make any significant difference in the etching performance. Since SiO₂ deposition is comparatively much more accessible, and well-established from experience in Si processing, the experiments disclosed herein moved forward with SiO₂. During the wet etching process, the 25% TMAH solution was heated to 80° C. and then immersed the ScₓAl₁₋ₓN samples in the solution.

FIG. 30A is a SEM image of Sc_{0.20}Al_{0.80}N after 3 mins of TMAH etching at 80° C. FIG. 30B is a SEM image of Sc_{0.20}Al_{0.80}N after removal of a SiO₂ hard mask. FIG. 30C is a SEM image of Sc_{0.20}Al_{0.80}N after removal of a SiO₂ hard mask for a different feature. FIG. 30D is a SEM image of Sc_{0.20}Al_{0.80}N after TMAH etching, the sample was prepared in negative tone (inverted mask).

Once etching starts, it can be visually seen that the ongoing chemical reactions create bubbles around the solution. Generally, once the whole ScₓAl₁₋ₓN layer is etched, the sample color changes. For Sc_{0.20}Al_{0.80}N, it only took 3 minutes to etch a 730 nm thick layer, ensuring an etch rate of 243 nm/min with approximately 870 to 900 vertical sidewalls, as shown in FIGS. 30A-30B, which can be considered as the state of the art when compared to other published works to date. See the tables of FIGS. 26 and 27. In FIGS. 30C-30D, the experiments disclosed herein also demonstrated that the same quality of etched profiles can be achieved using different patterns as well using an inverted mask.

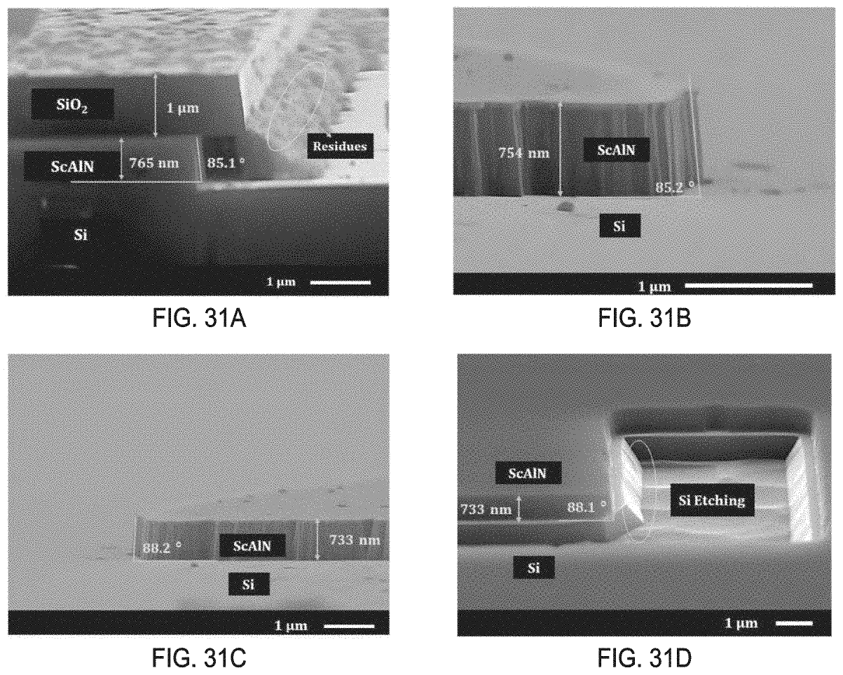

The same TMAH concentration and temperature were applied during the etching process of Sc_{0.40}Al_{0.06}N and Sc_{0.125}Al_{0.875}N and the results are shown in FIGS. 31A-31D. FIG. 31A is a SEM image of Sc_{0.40}Al_{0.60} after 9 mins of TMAH etching at 80° C. FIG. 31B is a SEM image of Sc_{0.40}Al_{0.60} after removal of a SiO₂ hard mask. FIG. 31C is a SEM image of Sc_{0.125}Al_{0.875}N after 2 mins of TMAH etching and removal of a SiO₂ hard mask. FIG. 31D is a SEM image of a Sc_{0.20}Al_{0.80}N over etching condition (Si undercut). The etching rate is found to be comparatively lower for Sc_{0.40}Al_{0.60}N (approximately 80 nm/min) compared to Sc_{0.125}Al_{0.875}N (350 nm/min). This result is consistent with other work, as shown in the tables of FIGS. 26 and 27. For the lower concentration, the results included a verticality of 88.2°±0.2° as shown in FIG. 31D, which is practically the same for what was found for the Sc_{0.20}Al_{0.80}N sample. However, as shown in FIG. 31B, the profile of the Sc_{0.40}Al_{0.60}N shows a verticality of approximately 85° C.

As the scandium concentration increases, usually the undercut (lateral) etching increases, but in the works disclosed herein were successful to reduce the lateral etching resulting in an undercut layer of less than 400 nm. See FIG. 31A. This was possible thanks to the combination of the annealing process and optimization of wet etching recipes. One critical observation of this wet etching process is that when the ScₓAl₁₋ₓN sample is withdrawn from the TMAH solution, the low solubility of scandium in alkaline solutions caused the formation of residues. Considering the TMAH chemistry and other reported work, it is highly likely that the residues were in the form of ScOₓH_{y} on the sample surface. As the scandium content increases, the more significant amount of residues will be deposited as shown in FIG. 31A, which will eventually slow down the etch process. Ultimately, amount of residues is likely to affect the device fabrication process. It has been mentioned in the literature that there is a dependency of the residues on the rinsing method and etching process. In the works disclosed herein, it has also been found that continuously stirring the ScₓAl₁₋ₓN sample during the etching process in TMAH reduces the formation of residues. Therefore, after the TMAH etching process, an effective DI water rinsing is recommended to remove the residues otherwise, TMAH can continue to keep the reaction ongoing. Since the DI water rinsing cannot remove the residues completely in this process, a HF-based cleaning (rinsing) process was implemented. Before using HF, proper rinsing with diluted DI is to be used, or else, if TMAH content exists in the samples during HF cleaning, there is a possibility of generating tetramethylammonium (TMA) salts through the following reaction, which will eventually make the situation more difficult for device fabrication.

N(CH₃)₄⁺OH⁻+HF→(CH₃)₄⁺F⁻+H₂O (5)

In the works disclosed herein, a diluted HF of approximately 3% to 5% was used to remove the SiO₂ hard mask. As shown in FIGS. 30B-29C and 31B-31C, HF does not influence the verticality or the surface roughness of the ScₓAl₁₋ₓN and contributes to removal of the residues (See FIGS. 30B-30C and 31B-31C-31D). The TMAH also etches the Si substrate once it etches down the whole ScₓAl₁₋ₓN layer, and the etching of Si is aggressive compared to ScₓAl₁₋ₓN (See FIG. 31D). This means that it may be possible to use this method to effectively release the ScₓAl₁₋ₓN from the Si substrate if the ScₓAl₁₋ₓN thin film is protected, both upper and underneath, by a layer that is resistant to TMAH. In the works disclosed herein, substantially vertical sidewalls were successfully maintained even for this over-etching situation of ScₓAl₁₋ₓN.

The following provides features of the disclosed experiments discussed above:
1. The deposition of ScₓAl₁₋ₓN films was conducted using a SPTS Sigma 200 deposition system, which employs reactive sputtering onto 150-mm Si <100> wafers. The Al/Sc concentration in the films was determined through energy-dispersive spectroscopy (EDS), and the measured Al/Sc ratios align with the anticipated values.
2. A SiO₂ film was used as a hard mask for etching ScₓAl₁₋ₓN. The SiO₂ layer was deposited using a CHA Mark-40 dielectric evaporator.
3. The process for patterning the SiO₂ hard mask involved the use of a Ni metal film as a mask, which was patterned using a lift-off process. Following the deposition of SiO₂, lithography was conducted utilizing the MLA 150 Advanced Maskless Aligner from Heidelberg Instrument.
4. The SiO₂ layer was etched using an ICP dry etch process after depositing Ni as the hard mask. The SiO₂ etch used CHF₃ (45 sccm) and O₂ (5 sccm) gases as the primary etchants during the process, where ICP, RF power, and chamber pressure were, respectively set at 400 W, 100 W, and 5 mTorr.
5. An intermediate anneal process was implemented before the ScₓAl₁₋ₓN etching step. This process aimed to remove any embedded impurities and repair any damaged ions within the ScₓAl₁₋ₓN film induced by the previous steps. Wet etching of the ScₓAl₁₋ₓN immediately after etching the SiO₂ layer resulted in surface roughness and was therefore avoided.
6. The wet etch step used a 25% concentrated TMAH (TMAH:Water in 1:3 ratio) solution at approximately 78° C. to 82° C. to etch ScₓAl₁₋ₓN (x=12.5%, 20%, 40%) films. The etching rate of Sc_{0.125}Al_{0.875}N, Sc_{0.20}Al_{0.80}N, and Sc_{0.40}Al_{0.60}N was found to be approximately 365 nm/min, 243 nm/min, and 81 nm/min, respectively.

In the work disclosed herein, an efficient process was successfully developed that is capable ensuring good vertical sidewalls of etching ScₓAl₁₋ₓN (x=12.5%, 20%, 40%) as well as reducing the amount of undercuts. The inventors have also analyzed the prospective reasons behind the factors that affect verticality during etching and demonstrated how the annealing process significantly improves the surface damage by reducing the ion-bombardment effect, which prevents lateral etching. As noted in the literature, the scandium content increases, the more difficult it is to etch in the presence of AOGs and formation of residues. Furthermore, the impact of high-temperature annealing may lead to optimizing the etching process for successful device fabrication. Finally, with the process disclosed herein ensuring vertical sidewalls, thus this process or variations thereof can be applied in the fabrication of piezoelectric devices like ring resonators, contour resonators, lamb wave resonators, RF filters, transducers, MEMS devices, photonics integrated circuits, and other similar devices.

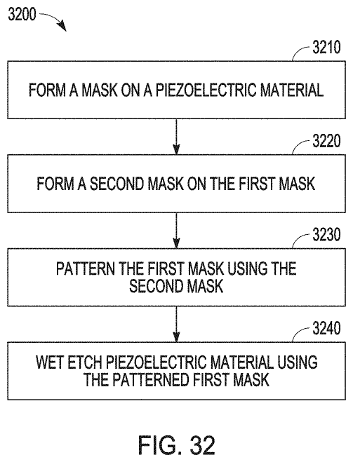

FIG. 32 is a flow diagram of features of an embodiment of an example method 3200 of processing piezoelectric material. At 3210, a first mask is formed on a piezoelectric material. The piezoelectric material can be positioned on a substrate. The substrate can be a silicon wafer. At 3220, a second mask is formed on the first mask. At 3230, the first mask is patterned using the second mask. At 3240, the piezoelectric material is wet etched using the patterned first mask. The wet etching forms structures of the piezoelectric material having vertical sidewalls within a specified deviation from the vertical.

Variations of method 3200 or methods similar to method 3200 can include a number of different embodiments that may be combined depending on the application of such methods and/or the architecture of systems including a piezoelectric material in which such methods are implemented. Such variations can include annealing the patterned first mask before wet etching the piezoelectric material. Variations can include patterning the first mask using an inductively coupled plasma dry etch to etch the first mask.

Variations of method 3200 or methods similar to method 3200 can include the piezoelectric material being a ScₓAl₁₋ₓN film and the first mask being a silicon oxide mask. The second mask can include nickel. Variations of method 3200 or methods similar to method 3200 can include wet etching the piezoelectric material by using tetramethyl ammonium hydroxide.

In various embodiments, an apparatus can comprise a piezoelectric material as a functional component. The piezoelectric material can have vertical sidewalls, where the vertical sidewalls deviate from ninety degrees by fifteen degrees or less. The deviation from ninety degrees can be by five degrees or less. The deviation from ninety degrees can be between approximately three degrees to about five degrees.

Variations of such an apparatus and its features, as taught herein, can include a number of different embodiments and features that can be combined depending on the application of such apparatus, the format of such apparatus, and/or the architecture in which such apparatus are implemented. Variations of such apparatus can include characteristics of the piezoelectric material being defined by an ICP dry etch process applied to the piezoelectric material. Variations of such apparatus can include the piezoelectric material being lithium niobate or ScₓAl₁₋ₓN. The apparatus can be a component in a radio frequency system, a MEMS, a phononic system, or a photonic system.

An inductively coupled plasma dry etch process can obtain a deep etching profile in a piezoelectric material, such as lithium niobate, with minimum roughness and substantially vertical sidewalls. In addition, quality metal masks can be achieved by employing a hydrogen-plasma treatment prior to the processing steps. Periodic interruption steps can be included in the plasma dry etch procedure followed by a chemical cleaning between each cycle to avoid thermal effect and minimize byproduct redeposition during the long etching process. Additionally, a deep etching profile in a piezoelectric material, such as a ScₓAl₁₋ₓN film, can be attained with minimum roughness and substantially vertical sidewalls using wet etching and a patterned mask, where the patterned mask is formed using another mask. The patterned mask can be annealed before wet etching the piezoelectric material.

Although specific embodiments have been illustrated and described herein, it will be appreciated by those of ordinary skill in the art that any arrangement that is calculated to achieve the same purpose may be substituted for the specific embodiments shown. Upon studying the disclosure, it will be apparent to those skilled in the art that various modifications and variations can be made in the devices and methods of various embodiments of the invention. Various embodiments can use permutations and/or combinations of embodiments described herein. Other embodiments will be apparent to those skilled in the art from consideration of the specification and practice of the embodiments disclosed herein. It is to be understood that the above description is intended to be illustrative, and not restrictive, and that the phraseology or terminology employed herein is for the purpose of description.

What is claimed is:

1. A method comprising:
forming a mask for a piezoelectric material on a substrate; and
etching, after forming the mask, the piezoelectric material using an inductively coupled plasma dry etch, forming a patterned structure in the piezoelectric material.

2. The method of claim 1, wherein the method includes:
forming the mask as a hard mask; and
applying a hydrogen-plasma treatment to the hard mask prior to using the inductively coupled plasma dry etch.

3. The method of claim 2, wherein the hard mask is a metal mask.

4. The method of claim 1, wherein the etching includes using periodic interruptions to the etching followed by a chemical cleaning between each cycle of the etching.

5. The method of claim 1, wherein forming the patterned structure in the piezoelectric material includes forming the patterned structure having vertical sidewalls.

6. The method of claim 1, wherein the piezoelectric material includes lithium niobate.

7. The method of claim 6, wherein the mask includes one or more of titanium, aluminum, or chromium.

8. The method of claim 6, wherein the inductively coupled plasma dry etch includes use of one or more fluoride-based chemistries.

9. The method of claim 8, wherein the one or more fluoride-based chemistries includes one or more of sulfur hexafluoride or trifluoromethane.

10. The method of claim 1, wherein forming the patterned structure in the piezoelectric material includes forming the patterned structure having vertical sidewalls that deviate from ninety degrees by five degrees or less.

11. A method comprising:
forming a first mask on a piezoelectric material, the piezoelectric material positioned on a substrate;
forming a second mask on the first mask;
patterning the first mask using the second mask; and
wet etching the piezoelectric material using the patterned first mask, forming structures of the piezoelectric material having vertical sidewalls within a specified deviation from the vertical.

12. The method of claim 11, wherein the method includes annealing the patterned first mask before wet etching the piezoelectric material.

13. The method of claim 11, wherein patterning the first mask includes using an inductively coupled plasma dry etch to etch the first mask.

14. The method of claim 11, wherein the piezoelectric material is a ScₓAl₁₋ₓN film and the first mask is a silicon oxide mask.

15. The method of claim 14, wherein the second mask includes nickel.

16. The method of claim 15, wherein wet etching the piezoelectric material includes performing a wet etch using tetramethyl ammonium hydroxide.

17. An apparatus comprising:
a piezoelectric material as a functional component, the piezoelectric material having vertical sidewalls, the vertical sidewalls deviate from ninety degrees by fifteen degrees or less.

18. The apparatus of claim 17, wherein characteristics of the piezoelectric material are defined by an inductively coupled plasma dry etch process applied to the piezoelectric material.

19. The apparatus of claim 17, wherein the piezoelectric material is lithium niobate or ScₓAl₁₋ₓN.

20. The apparatus of claim 17, wherein the apparatus is a component in a radio frequency system, a micro-electromechanical system, a phononic system, or a photonic system.
